(19) United States
(12) Patent Application Publication
(10) Pub. No.: US 2025/0254851 A1
(43) Pub. Date: Aug. 7, 2025

(54) Cloud-Based Electronic Manufacturing Systems

(71) Applicant: Adom Industries, Inc., Fort Worth, TX (US)

(72) Inventors: John Lauer, Bartonville, TX (US); Raymond Kholodovsky, Morristown, NJ (US); Adonis Lysandrou, Dallas, TX (US); James Morin, Roanoke, TX (US); Andrew Owens, Flower Mound, TX (US); Adrian Wowk, Lewisville, TX (US)

(21) Appl. No.: 19/046,334

(22) Filed: Feb. 5, 2025

Related U.S. Application Data
(60) Provisional application No. 63/550,161, filed on Feb. 6, 2024.

(51) Int. Cl. H05K 13/04; B65G 1/10

(52) U.S. Cl. CPC H05K 13/041; B65G 1/10; H05K 13/0406

(57) ABSTRACT

A network-based manufacturing system for electronic devices includes a work cell, a warehouse having a plurality of storage bins for holding electronic components, and a shuttle for moving the electronic components from the plurality of storage bins to the work cell. In response to receiving a request to build an electronic device, the shuttle robotically transports electronic components from the warehouse to the work cell and the electronic device is assembled within the work cell. A work cell includes a framework having of a plurality of support beams; a plurality of pincers moveably coupled to the framework; a first scaffold base coupled to the framework; a plurality of motors coupled to the framework or pincers. The pincers are capable of manipulating and assembling the electronic components. Methods for use of the system and work cell are used to assemble, prototype, operate, or test electronic device or circuits.

### RELATED APPLICATION

This application claims the benefit of U.S. Provisional Patent Application No. 63/550,161, filed on Feb. 6, 2024, entitled, “Cloud-Based Electronic Manufacturing Systems,” the disclosure of which is hereby incorporated by reference for all purposes.

### COPYRIGHT NOTICE

A portion of the disclosure of this patent document contains material that is subject to copyright protection. The copyright owner has no objection to the facsimile reproduction by anyone of the patent document or the patent disclosure, as it appears in the Patent and Trademark Office patent files or records, but otherwise reserves all copyright rights whatsoever. The following notice applies to the software and data as described below and in the drawings that form a part of this document: Copyright 2024 Adom Industries, Inc. All Rights Reserved.

### TECHNICAL FIELD

This application is directed, in general, to electronic chips, circuits, mechatronics, and assemblies, and more specifically, to cloud-based electronic manufacturing systems and methods for prototyping and manufacturing electronic chips, circuits, mechatronics, and assemblies.

### BACKGROUND

The following discussion of the background is intended to facilitate an understanding of the present disclosure only. It should be appreciated that the discussion is not an acknowledgement or admission that any of the material referred to was part of the common general knowledge at the priority date of the application.

With the passing of the CHIPS Act and with the desire for a more robust electronics manufacturing capacity in the United States and elsewhere in the world, there is an increased desire to improve prototyping, testing, and production of circuits. On method for assembling and prototyping new electronic devices is the breadboard method. The breadboard approaches leave much to be desired. While methods and systems are known for prototyping and manufacturing new electronic devices, improvements are desired.

### SUMMARY

In one illustrative embodiment, a network-based manufacturing system for electronic devices includes a plurality of work cells, a warehouse having a plurality of storage bins for holding electronic components, a shuttle for moving the electronic components from the plurality of storage bins to the plurality of work cells, and a control unit having at least one processor and one non-transitory memory and being communicatively coupled at least to the plurality of work cells and the shuttle. Each work cell of the plurality of work cells includes a plurality of robotic arms for holding, releasing, and moving items, and a work surface for supporting electronic devices. The shuttle includes one or more elevated rails suspended above the plurality of work cells and above the plurality of storage bins, a transport platform for releasably coupling to electronic components to be transported, a shuttle drive having a motor coupled to the one or more elevated rails for moving the shuttle along the one or more elevated rails, and a plurality of extension arms coupled to the transport platform and to the shuttle drive for holding and positioning the transport platform at a desired height.

In one illustrative embodiment, a network-based manufacturing system for electronic circuits includes a plurality of work cells, a warehouse having a plurality of storage bins, a shuttle for moving items from the plurality of storage bins to the plurality of work cells, a control unit communicatively coupled to the shuttle and the plurality of work cells, and a user interface for receiving an electronic design schematic. The control unit has a processor and non-transitory memory operable to instruct the shuttle to obtain necessary components for the electronic design schematic from the warehouse, deliver the components to an assigned work cell, and to instruct the work cell to assemble the components into an electronic device.

In one illustrative embodiment, a method for prototyping an electronic device by a user at a remote location over a network, the method includes the steps of receiving over a network a design of an electronic device, determining the components necessary to build the electronic device, locating the components necessary to build the electronic device within a warehouse, robotically collecting the components necessary to build the electronic device from the warehouse, robotically delivering the components necessary to build the electronic device to a work cell using a shuttle, and robotically assembling the components necessary to build the electronic device using at least one robotic arm of the work cell by using one or more pincers of the at least one robotic arm to place the components at designated locations on a work surface of the work cell according to the design of the electronic device.

In one illustrative embodiment a work cell includes at least one scaffold base for supporting the assembly of an electronic device or an electronic circuit; a rigid framework, for supporting the at least one scaffold base and coupled to the at least one scaffold base; at least one pincer support slidably coupled to the rigid framework; at least one pincer, slidably coupled to the at least one pincer support, for manipulating components of the electronic device or of the electronic circuit; a first drive unit, including a first electric motor, coupled to the at least one pincer support, wherein the first drive unit is capable of moving the at least one pincer support in a first direction along a length of a first member of the rigid framework; a second drive unit, comprising a second electric motor, coupled to the at least one pincer, for moving the at least one pincer in a second direction along a length of the at least one pincer support. The at least one scaffold base comprises a flat rigid material having a plurality of apertures arranged in a repeating geometric pattern. At least some of the apertures of the plurality of apertures are sized and configured to receive machine pins. The at least one pincer includes a pincer bar slidably coupled to the at least one pincer support; a third drive unit, inlcuding a third electric motor, coupled to the pincer bar; and a pincer subassembly coupled proximate to a first end of the pincer bar. The third drive unit is capable of moving the pincer bar in a third direction. Movement of the pincer bar in the third direction results in movement of the pincer subassembly in the third direction. The pincer subassembly includes a plurality of pincer arms coupled to a pincer arm support and a fourth drive unit, including a fourth electric motor, for moving the least one pincer arm that is slidably coupled to the pincer arm support along a length of the pincer arm support. The at least one of the pincer arms is slidably coupled to the pincer arm support.

In one illustrative embodiment, a work cell for assembling and prototyping an electronic device includes a framework comprised of a plurality of support beams; a plurality of pincers moveably coupled to the framework; a first scaffold base coupled to the framework comprising a flat surface for assembly of an electronic device; a plurality of motors coupled to the framework or pincers for moving the pincers within the work cell. Thea plurality of apertures are formed within the first scaffold base for retaining a plurality of electronic components of the electronic device. Each of the plurality of pincers is capable of clamping onto, moving, and placing each of the electronic components within the work cell. The work cell is communicatively coupled to a control unit for transmitting commands from the control unit to the work cell. The commands comprise instructions for the work cell to assemble the electronic device.

Other systems and methods are described below.

### DESCRIPTION OF THE DRAWINGS

Illustrative embodiments of the present disclosure are described in detail below with reference to the attached drawing figures, which are incorporated by reference herein and wherein:

FIG. 1 is a schematic, perspective view of a portion of an illustrative embodiment of a cloud-based electronic manufacturing system;

FIG. 2 is a block diagram of a portion of an illustrative embodiment of a cloud-based electronic manufacturing system;

FIG. 3 is a schematic, perspective view of a portion of an illustrative embodiment of a warehouse and a portion of a shuttle of a cloud-based electronic manufacturing system;

FIG. 4 is a schematic, perspective view of a portion of an illustrative embodiment of a warehouse of a cloud-based electronic manufacturing system;

FIG. 5 is a schematic, perspective view of an illustrative embodiment of a work cell of a cloud-based electronic manufacturing system;

FIG. 6 is a schematic, perspective view of an illustrative embodiment of a work cell and a portion of a shuttle of a cloud-based electronic manufacturing system;

FIG. 7 is a schematic, perspective view of a portion of an illustrative embodiment of a portion of a work cell of a cloud-based electronic manufacturing system;

FIG. 8 is a schematic, perspective view of an illustrative embodiment of a camera system of a work cell of a cloud-based electronic manufacturing system;

FIG. 9 is a schematic, perspective view of a portion of an illustrative embodiment of a camera system of a work cell of a cloud-based electronic manufacturing system;

FIG. 10 is a process flow diagram of an illustrative embodiment of a method for assembling or operating electronic devices utilizing a cloud-based electronic manufacturing system;

FIG. 11 is a process flow diagram of an illustrative embodiment of a build routine for assembling electronic devices utilizing a cloud-based electronic manufacturing system;

FIG. 12 is a process flow diagram of an illustrative embodiment of an operate routine for assembling electronic devices utilizing a cloud-based electronic manufacturing system;

FIG. 13 is a perspective view of an illustrative embodiment of a work cell;

FIG. 14 is a detailed view of a portion to the illustrative embodiment of the work cell of FIG. 13;

FIG. 15 is a detailed view of a portion to the illustrative embodiment of the work cell of FIG. 13;

FIG. 16 is a detailed view of a portion to the illustrative embodiment of the work cell of FIG. 13;

FIG. 17 is a detailed view of a portion to the illustrative embodiment of the work cell of FIG. 13;

FIG. 18 is a detailed view of a portion to the illustrative embodiment of the work cell of FIG. 13;

FIG. 19 is a detailed view of a portion to the illustrative embodiment of the work cell of FIG. 13;

FIG. 20 is a detailed view of a portion to the illustrative embodiment of the work cell of FIG. 13;

FIG. 21 is a partial view of scaffold bases and machine pins of an illustrative embodiment of a work cell;

FIG. 22 is a portion of an illustrative embodiment of a scaffold base of a work cell;

FIG. 23 is a perspective view of an illustrative embodiment of a scaffold base of a work cell;

FIG. 24 is a perspective view of an illustrative embodiment of a scaffold base of a work cell;

FIG. 25 is a perspective view of a portion of a pincer and a portion of a machine pin of a work cell;

FIG. 26 is a perspective view of a portion of a pincer and a portion of a machine pin of a work cell;

FIG. 27 is a perspective view of a portion of illustrative scaffold bases of an illustrative work cell;

FIG. 28 is a perspective view of an illustrative embodiment of a retainer clip for retaining scaffold bases of an illustrative embodiment of a work cell;

FIG. 29 is a perspective view of an illustrative embodiment of a machine pin for use in an illustrative embodiment of a work cell;

FIG. 30 is a perspective view of an illustrative embodiment of a machine pin for use in an illustrative embodiment of a work cell;

FIG. 31 is a perspective view of an illustrative embodiment of an electronic component for use in a work cell;

FIG. 32 is a perspective view of an illustrative embodiment of an electronic component for use in a work cell; and

FIG. 33 is a partial plan view of an illustrative electronic device assembled on a scaffold base of an illustrative embodiment of a work cell.

### DETAILED DESCRIPTION

In the following detailed description of the preferred embodiments, reference is made to the accompanying drawings that form a part hereof, and in which is shown, by way of illustration, specific embodiments in which the disclosure may be practiced. These embodiments are described in sufficient detail to enable those skilled in the art to practice the disclosure, and it is understood that other embodiments may be utilized and that logical structural, mechanical, electrical, and chemical changes may be made without departing from the spirit or scope of the disclosure. To avoid detail not necessary to enable those skilled in the art to practice the disclosure, the description may omit certain information known to those skilled in the art. The following detailed description is, therefore, not to be taken in a limiting sense, and the scope of the present disclosure is defined only by the claims.

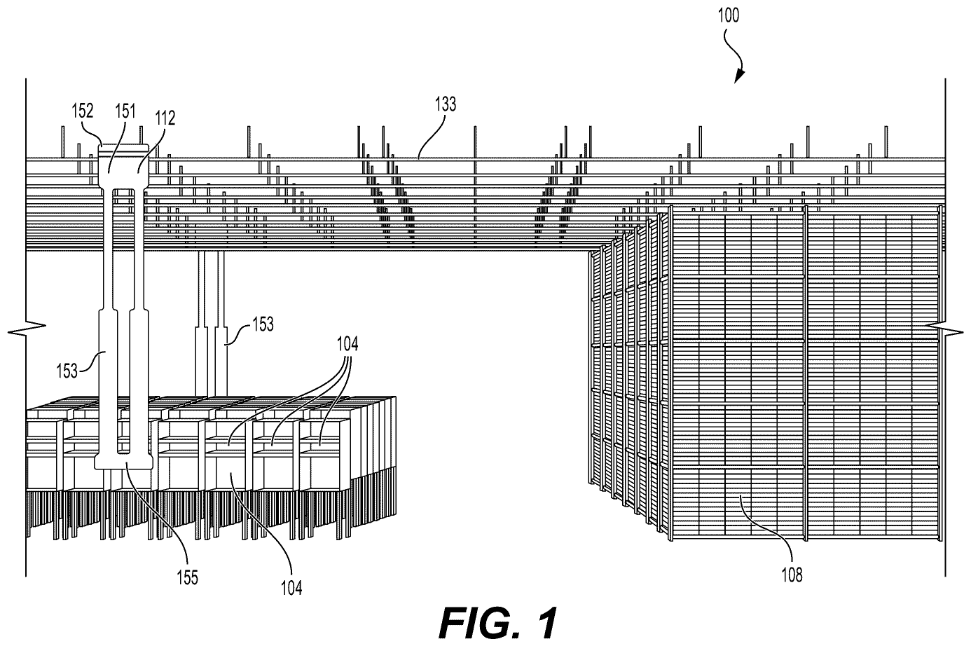

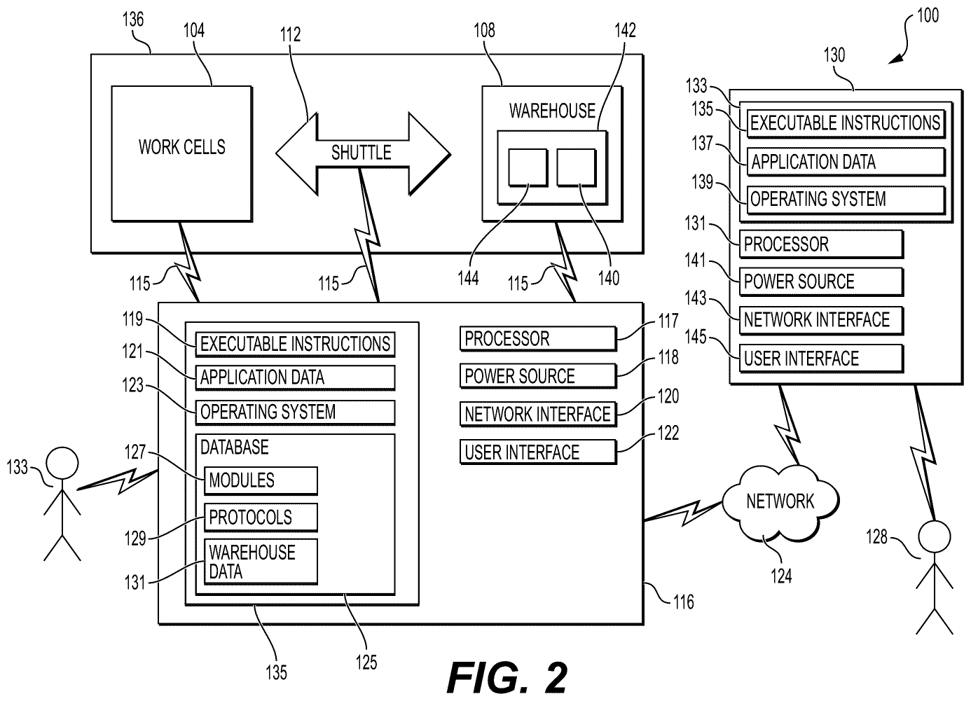

Referring to the figures, and initially to FIGS. 1 and 2, and primarily to FIG. 1, a cloud-based electronic manufacturing system 100 is presented. The system 100 may provide for the building and testing of chips, circuits, and assemblies. In one embodiment, the system 100 is a cloud factory that allows one to prototype electronics; to build circuit boards; to test out new chips from chip factories; build full assemblies including all accessories of the circuits such as displays, sensors, motors, lights or anything connected to circuits including test equipment, mechanical structures, enclosures of the assembly; collaborate with co-workers; to run testing cycles; to learn electronics; and to have open-source electronics where others can test a circuit and build on each other's work if desired.

In one aspect of an illustrative embodiment, the system 100 is a schematic validation system. With the system 100, one does not have to order parts or wait for circuit boards to get made. In some embodiments, the system 100 using automation techniques and equipment, assembles a desired electronic device or component utilizing stock components. In some embodiments, the system 100 may include the ability to build a virtual version of an electronic device or components prior to assembly of the physical electronic component or device. In some embodiments, depending on the complexity of the electronic component or device, the system 100 may assemble the electronic component or device within a few days or even a few hours. The result being that the system 100 is able to verify the schematic of the electronic component or device in a timely and efficient manner.

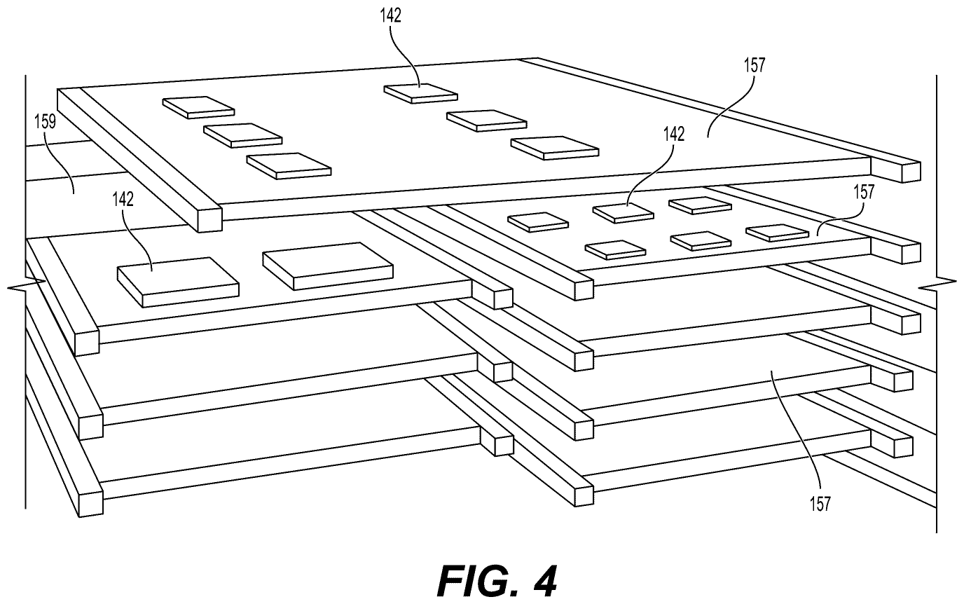

The system 100 may include a plurality of work cells 104 where electronic devices; circuits, or assemblies are built, a warehouse 108 where components 142 (FIG. 4) (including partial circuits and assemblies) are stored; a shuttle 112 (or transport system) for moving components from the warehouse 108 to a work cell 104; and a control unit 116 (FIG. 2) to control the system 100 that is accessible via a network 124 (FIG. 2), such as the internet.

The system 100 utilizes automation and robotic systems and protocols to prototype electronic devices. In general, a design of an electronic device is inputted into the system 100. The electronic device may contain any number of components 142 (FIG. 4). In order to build and prototype the electronic device, it is necessary to gather all of the components 142 and to assemble and connect the components 142 into the electronic device.

Not limiting examples of components 142 include resistors, diodes, transformers, battery packs, processors, PCB's with other integrated electronic components, memory chips, wires, connectors, jumpers, etc. Components 142 may also include subassemblies of other components 142.

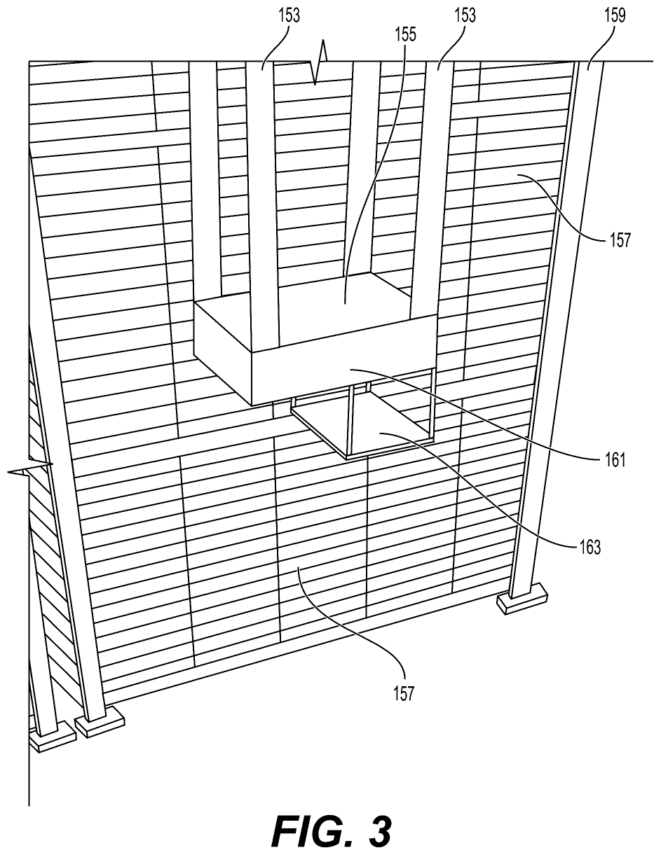

The components 142 are stored within the warehouse 108. The warehouse 108 may include a plurality of shelves, bins, trays, etc. for storing the components 142 (FIGS. 3 and 4). The shuttle 112 and the control unit 116 coordinate and control the movements of the components 142 between the warehouse 108 and the work cells 104.

Upon receiving a request to build or prototype an electronic device, instructions are sent by the control unit 116 to the shuttle 112 instructing the shuttle 112 to gather the necessary components 142 from the warehouse 108. The instructions may include movement instructions or information such as the identity of the components 142 needed for the prototype, the number of each component 142 needed for the prototype, the location within the warehouse 108 of particular components 142 needed for the prototype, or other similar information. The location of the components 142 within the warehouse 108 may include information identifying a row, column, tray, bin, etc. within the warehouse 108 where the desired component 142 is located.

The shuttle 112 utilizes a plurality of rails 133 suspended above the warehouse 108 and the work cells 104 to maneuver between and among the warehouse 108 and the work cells 104. A shuttle drive 151 is coupled to the plurality of rails 133, so that the shuttle drive 151 can move the shuttle 112 along each of the plurality of rails 133. In this manner, the shuttle 112 may move throughout the system 100 to various locations within the warehouse 108 and to each of the work cells 104. In some embodiments, the shuttle drive 151 includes a motor coupled to a plurality of wheels 152 (FIG. 1). The motor drives the plurality of wheels, which ride along the plurality of rails 133.

Utilizing the plurality of rails 133, which form a coordinated grid, and the shuttle drive 151, the shuttle 112 moves to the particular locations within the warehouse 108 where particular components 142 that are needed for a prototype electronic device are located.

The shuttle 112 also includes extension arms 153 coupled to the shuttle drive 151. The extension arms 153 are able to retract (upwards as shown in FIG. 1) and to extend (downwards as shown in FIG. 1) to raise and lower a platform 155. The platform 155 is raised or lowered as needed to access a desired level within the warehouse 108 or a work cell 104. FIG. 1 shows two extension arms 153 accessing a work cell 104.

In this manner, the shuttle 112 is able to navigate the plurality of rails 133 to a desired location, e.g. above a warehouse location holding a desired component 142. The extension arms 153 are extended or retracted to the correct height, i.e. the height within the warehouse 108 where the desired component 142 is located. Then the desired component 142 is loaded onto the platform 155. The height of the platform 155 may then be adjusted, upwards or downwards, to allow for a clear path of travel for the shuttle 112 to the particular work cell 104 to which the component 142 is to be delivered. Then the shuttle 112, utilizing the plurality of rails 133 and the shuttle drive, relocates to the location of the particular work cell 104 to which the component 142 is to be delivered. Then extension arms 153 may then be raised or lowered to the correct height for delivery of the particular component 142 to the work cell 104, at which point the particular component 142 can be offloaded from the platform 155 into the work cell 104 for use in the electronic device to be assembled. In some embodiments, the work well 104 may include a tray that extends outward to receive the components 142.

In some embodiments of the system 100, the shuttle 112 is not suspended and the plurality of rails 133 is omitted. In some embodiments, the shuttle 112 is self propelled unit having analogous features as the work cells 105, 640 described herein for grabbing, manipulating, and positioning components 142 on the scaffold base 832. The shuttle 112 may be moved throughout the warehouse 108 and the work cells 104 by a plurality of wheels coupled to the shuttle 104 that are driven by electric motors. In some embodiments, the shuttle 112 may included the components of a general or special purpose computer for receiving or transmitting data or commands between other components of the system 100 and for executing and processing commands necessary for the shuttle 112 to gather required components 142 and delivering those components 142 to the work cell 104. In some embodiments, the shuttle 142 is a mobile work cell 104, 640 that is able to be remotely or robotically controlled. In some embodiments, the heights of the shuttle 112 or the height of scaffold bases 832 or pincers subassemblies 728 (as described in detail below) of the shuttle 112 is controlled using telescoping frame members of the shuttle 112.

In some embodiments, the shuttle 112 may be a robotic or remotely controlled elevator type device that is mounted to or proximate to the warehouse 108.

Referring now primarily to FIG. 2, the control unit 116 typically is a computing device, such as a general purpose computer or special purpose computer, that utilizes one or more computer processors 117 to execute computer instructions 119 stored on non-transitory memory 135 to operate the system 100, including communicating with users 128 through user devices 130, interacting with and sending commands to the work cells 104, interacting with and sending commands to the shuttle 112, interacting with and sending commands to the warehouse 108, interacting or executing with the available modules 127 or protocols 129, etc. The user device 130 may be, for example, a smartphone, tablet, laptop computer, desktop computer, or other device.

The control unit 116 also has a power source 118 for providing electrical power to operate the control unit 116 and its components. The control unit 116 has a network interface 120 for providing network communications between the control unit 116 and other components of the system 100 such as the user device 130, the work cells 104, the shuttle 112, and the warehouse 108. The control unit 116 may include a backend user interface 122. The backend user interface 122 allows for a backend user 133 to operate and interact with the control unit 116. This allows for the backend user 133 to perform operations on the control unit 116, such as modifying the executable instructions 119, application data 121, or database 125 of the control unit 116.

The non-transitory memory 135 of the control unit 116 may be used to store the executable instructions 119, application data 121, an operating system 123, and the database 135. The database 135 may include modules 127, protocols 129, and warehouse data 131. The modules 127 may store predefined electronic component designs, which allow for a user 128 to call a desired module 127 to obtain a desired electronic component or subcomponent without having to design the electronic component from scratch. Modules 127 may therefore be used to define common electronic subcomponents for use in electronic devices that the user 128 desires the system 100 to build. The protocols 129 may include predefined methods, operations, or procedures related to electronic devices to be operated or tested using the system 100. Protocols 129, therefore, may be used to store common procedures used in testing or operating electronic devices.

The user 128 interacts with the system 100 through a network connection 124. The user 128 typically uses a user device 130, such as a general purpose computer or smart phone, that utilizes one or more computer processors 131 to execute computer instructions 135 stored on non-transitory memory 133 to execute a user interface application and to provide a communication link between the user 128 and the remainder of the system 100. The user 128 may, through such connection, input the requirements, components, parameters, etc. necessary to assemble or test an electronic device and, in some embodiments, may monitor the build or testing process.

The user device 130 includes non-transitory memory 133. The executable instructions 135, application data 137, and an operating system 139 may be stored in the non-transitory memory 133. The user device 130 also includes a power source 141 for providing electrical power to operate the user device 130 and the components of the user device 130. The user device 130 includes a network interface 143 for providing a network communication link between the user device 130 and the control unit 116, via the network 124. The user device 130 also includes a user interface 145, which allows for the user 128 to interact with and use the user device 130. The user interface 145 may include a display screen, mouse, keyboard, and other similar input and output devices that allow information to be presented to the user 128 and that allow for the user 128 to input information into the user device 130.

The executable instructions 135 or application data 137 may contain the information necessary for the user device 130 to operate a user interface application using the processor 131 for allowing the user 128 to interact with the user device 130 and the system 100. The user interface application may allow for the user 128 to input specific requests to build, test, or operate electronic devices that the user 128 wishes to prototype or manufacture using the system 100. The input of the user 128 is translated to instructions for the system 100 to act upon. Such requests are transmitted to the control unit 116 through the network 124 using the network interface 129 and the network interface 143.

The control unit 116, upon receiving such instructions from a user device 130, generally processes the request and transmits commands to the other components of the system 100 to assemble or test the electronic device that the user 128 desires to prototype. For example, the control unit 116 may analyze the the request to determine that the request is a build request, determine what components 142 are necessary to build the requested device, make a determination as to whether the components are available within the warehouse 108, instruct the shuttle 112 to obtain the components from the warehouse 108, instruct the shuttle 112 to deliver the components 142 to the assigned work cell 104, and instruct the work cell 104 to assemble the components 142 into the electronic device that the user 128 requested to be built.

In another aspect, the system 116 may be used to operate or test electronic devices utilizing the work cells 104. For example, a user 128 may use the user device 130 to transmit a test or operation request to the system 100. The test or operation request is received by the control unit 116 through the network connection 124.

Upon receipt of the test or operation request, the control unit 116 executes computer instructions 119 to send commands, over connections 115, to the work cell 104 containing the device to be tested or to which the operation applies. The work cell 104 provides the necessary connections to the electronic device (e.g., inputs, outputs, power supplies, network connections, sensor connections, etc.) to perform the test or operation on the electronic device.

Data regarding the output of the test or operation may be transmitted over connection 115 to the control unit 116, which may, in turn pass such information to the user 128 through the network 124 and user device 130. In some embodiments, such data is transmitted in real time or near real time to provide direct results of the test or operation to the user 128. In some embodiments, the user 128 may be able to modify the test or operation parameters in real time or near real time.

The control unit 116 may be distributed at various locations in the system 100 and may include a plurality of processors and non-transitory memories. The control unit 116 may be communicatively coupled to the work cells 104, warehouse 108, shuttle 112, and other components by wired connections or wireless connections 115 as those skilled in the art will appreciate. The work cells 104, warehouse 108, and shuttle 112 may all be in a single facility 136. Alternatively, the work cells 104, warehouse 108, and shuttle 112 may be disposed across multiple facilities.

The warehouse 108 is used to physically store the components 142 needed to assemble electronic devices for prototyping or manufacturing. The electronic components 142 may include any number or type of electronic components needed for such devices, such as resistor, capacitors, inductors, diodes, transistors, LEDs, relays, switches, connectors, processors, sensors, etc, and the like, to name a few. The electronic components 142 may also include integrated circuits, such as preassembled PCBs. The electronic components 142 may also include preassembled sub-components to be used in the electrical devices to be prototyped.

The components 142 may include publicly available contents 140. Publicly available contents 140 being common components 142 of electrical devices that all users 128 are able to access. The warehouse 108 may also include privately available components 144. Privately available components 144 being components 142 that the user 128 has sent to the facility where the system 100 is located for storage in the warehouse 108. Privately available components 144 may be, for example, particular components 142 of interest or use to the user 128 or preassembled electronic components or devices, such a PCBs, for use in the electronic device or component that the user 128 desires to have the system 100 assemble, validate, prototype, or test. Access to privately available components 144 may be limited to particular users 128 associated with particular privately available components 144.

Referring now primarily to FIGS. 3 and 4, the warehouse 108 will be further described. FIG. 3 depicts a portion of the warehouse 108 and a portion of the shuttle 112. The shuttle 112 is depicted locating or picking up components 142 (FIG. 4) from the warehouse 108.

The warehouse 108 includes a plurality of storage trays or bins 157 disposed within shelving units 159. The storage bins 157 may be slidably mounted to the shelving units 159 so that the storage bins 157 can be extended outward to allow better access the components 142 within each storage bin 157. FIG. 4 depicts a detailed view of some of the storage bins 157 of the warehouse 108, with the topmost storage bin 157 extended outward for access to the components 142 stored within this storage bin 157. The extension and retraction of the bins 157 may be accomplished using electronically driven motors, servos, belts, gears, etc. The components 142 may be held in a known grid on each shelf to facilitate pickup. The components 142 may use pin holes or other holding devices.

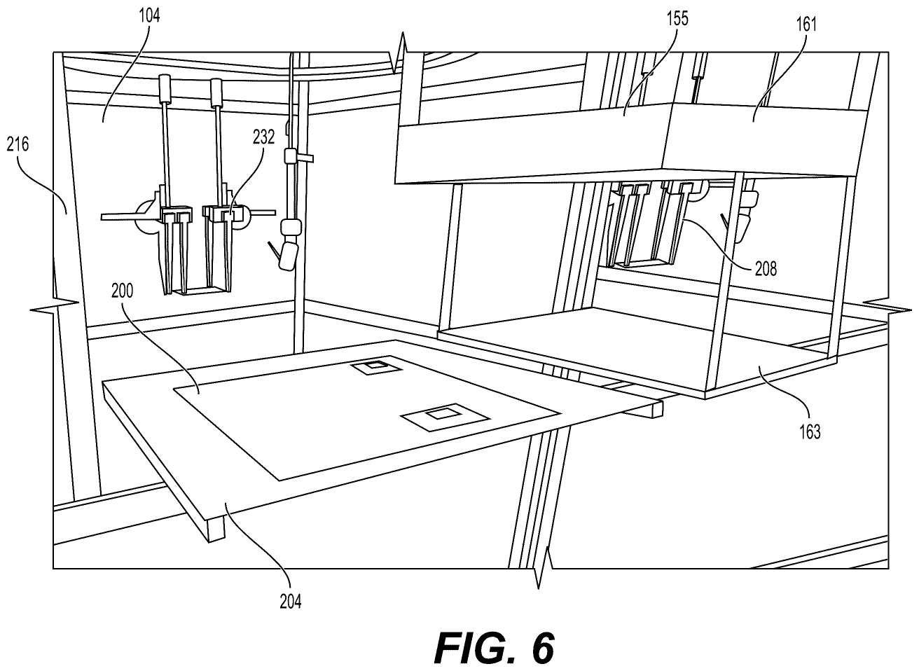

As shown in FIG. 3, the platform 155 of the shuttle 112 may include an upper portion 161 and a tray portion 163. The upper portion 161 of the platform 155 may include robotic arms, pinchers, or other components for removing the components 142 from the storage bins 157 and placing them onto the tray portion 163 (SEE FIG. 6). The components 142 may then ride on the tray portion 163 while being transported to the particular work cell 142 where the components 142 are needed. In the alternative, the robotic arms, pinchers, or other components for removing the components 142 from the storage bins 157 may be a part of the warehouse 108 instead of being part of the shuttle 112.

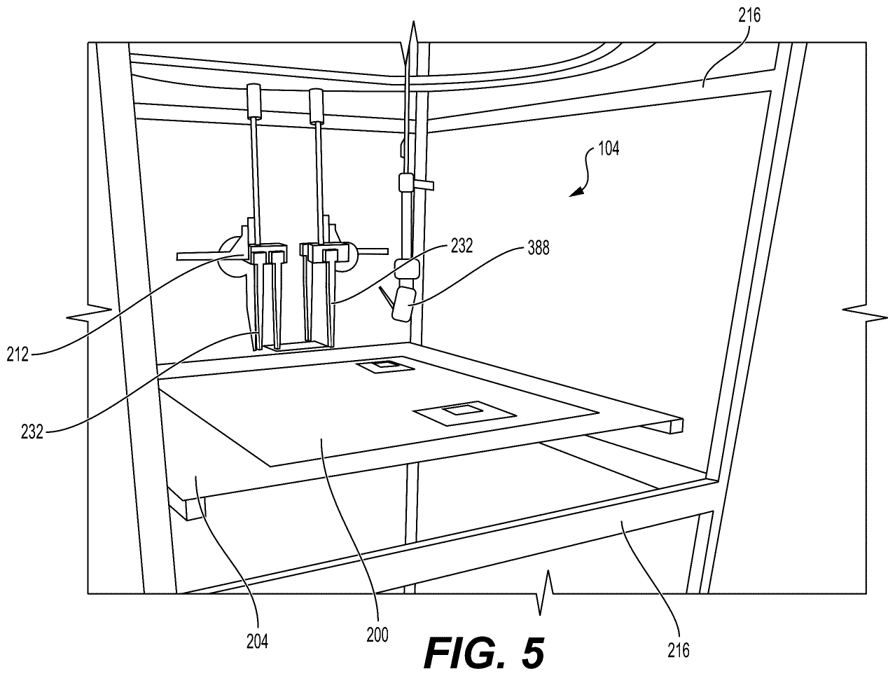

Referring now to FIGS. 5-7, and primarily and initially to FIG. 5, the plurality of work cells 104 are described in more detail. The system 100 assembles electronic devices within the plurality of work cells 104. An assigned work cell 104 may be used to build a particular electronic device. As used herein, an electronic device includes any electronic device that may be assembled from a variety of components and includes circuits or assemblies and partial circuits or partial assemblies that may be intended to be further incorporated into other devices. The same work cell 104 that is used to assemble an electronic device may also be used for testing or operating the electronic device. In the alternative, testing may be done at a different work cell 104 within the facility 136 (FIG. 2).

The building of an electronic device at the work cell 104 is accomplished with a patterned scaffold 200 that has pinholes for installing and retaining components 142. The scaffold 200 may be supported on a work cell drawer 204 that moves in and out of the work cell 104 to facilitate the arrival of components 142 from the shuttle 112 or removal of the completed electronic device by the shuttle 112.

The shuttle 112 (FIG. 6) may deliver components 142 to the work cell 104 that has been assigned for assembly of a particular electronic device. The shuttle 112 may include a plurality of elevated rails 133 (FIG. 1) that are suspended above the work cells 104 and the warehouse 108, as described above, to deliver the components 142 to the work cell 104. As also described above, the shuttle 112 may include an upper portion 161 and a tray portion 163 that are coupled to one or more extension arms 153 (FIG. 1) that function like an elevator moving vertically to align the upper portion 161 or the tray portion 163 at the height of the assigned work cell 104.

As shown in FIG. 6, the upper portion 161 may include one or more transportation pincers 208 suspended over the tray portion 163. The transportation pincers 208 may be robotic arm like devices that are capable of moving the components 142 from the tray portion 163 to the scaffold 200 of the work cell 104. The transportation pincers 208 may also be used to move components 142 from the trays 157 of the warehouse 108 to the tray portion 163 when the shuttle 112 is used to collect the components 142 from the warehouse 108.

The work cell drawer 204 is moveable between a load position or extended position as shown in FIG. 6 and a build position or not extended position as shown in FIG. 5. In the load position the work cell drawer 204 is extended outward from the work cell 104 so that the scaffold 200 is accessible to the transportation pincers 208 of the shuttle 112. In the build position, the work cell drawer 204 is inside the work cell 104 so that the work cell components may manipulate the components 142 located on the scaffold 200. The work cell drawer 204 may be moved from the build position to the load position, and vice versa, by electronically driven motors, actuators, belts, gears, etc. coupled between a work cell frame 216 and the work cell drawer 204.

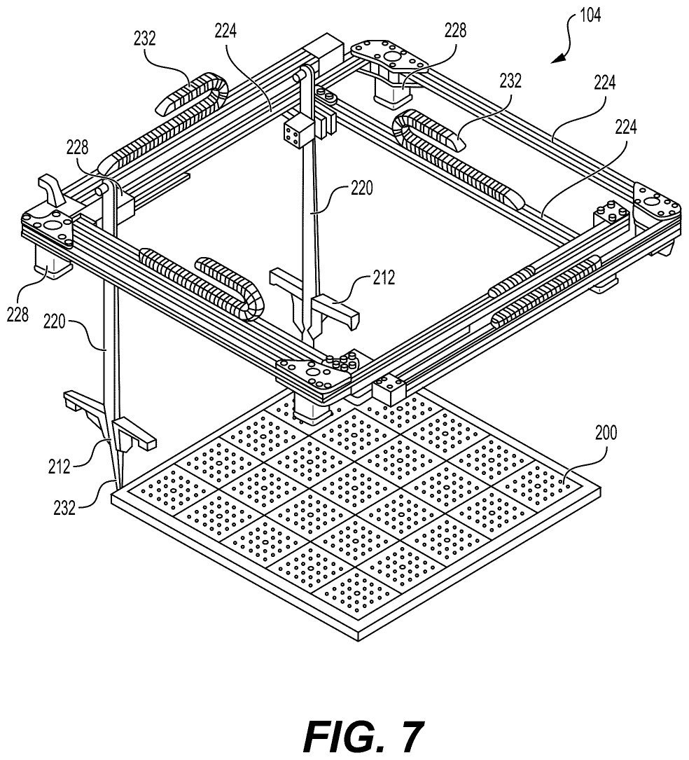

Still referring to FIGS. 5-7, and primarily to FIG. 7, further details of an illustrative embodiment of the work cell 104 will be discussed. One or more work cell pincers 212 may be suspended by pincer legs 220 that are moveable along work cell rails 224 that are moveable as well to allow the work cell pincers 212 to be positioned at any location over the work cell drawer 204. The work cells rails 224 are coupled to the work cell frame 216 (FIG. 5) The work cell pincers 212 may be elevated or lowered or may be able to retract or extend to facilitate movement of the components 142 within the work cell 104. While two work cell pincers 212 are shown, it should be understood that three, four, five, six or more work cell pincers 212 may be used.

The work cell pincer legs 220 and at least some of the work cell rails 224 are moveable as described above, i.e., the pincer legs 220 may be moved along work cell rails 224 and at least some work cell rails 224 may be moved along other work cell rails 224. In one illustrative embodiment, these movements are achieved by using of a plurality of stepper motors 228 coupled to the pincer legs 220 or work cell rails 224. In some embodiments, chain or belt drives are further coupled to the work cell rails 224, pincer legs 220, or stepper motors 228 to achieve the movement of the work cell pincer legs 220 or the work cell rails 224.

In this manner, the work cell pincers 212 may be manipulated so that the work cell pincers 212 can be moved over the scaffold 200. The work cell pincers 212 may also be elevated or lowered within the work cell 104. The work cell pincers 212 include pincer arms 232. The pincer arms 232 are designed to be closed and opened so that the pincer arms 232 may be used to pick up, move, and manipulate components 142. The work cell pincers 212 may also yaw and pitch.

In this manner, the work cell 104 is able to assemble the electronic devices, as described above. Upon delivery of the components 142 to the work cell 104 by the shuttle 112, the work cell pincers 212 move and manipulate the components 142 to assemble the components 142 into the electronic device to be built.

It should be appreciated, that other methods of robotically moving, manipulating, or assembling the components 142 may be used.

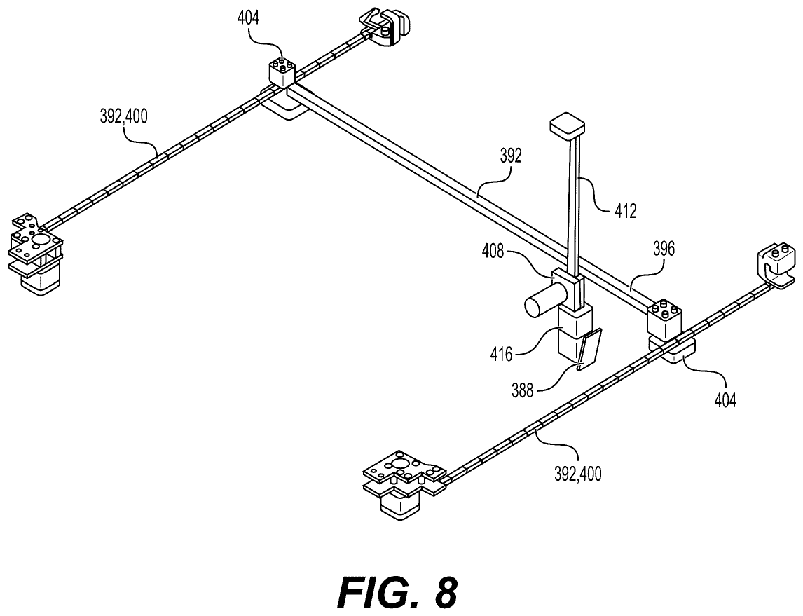

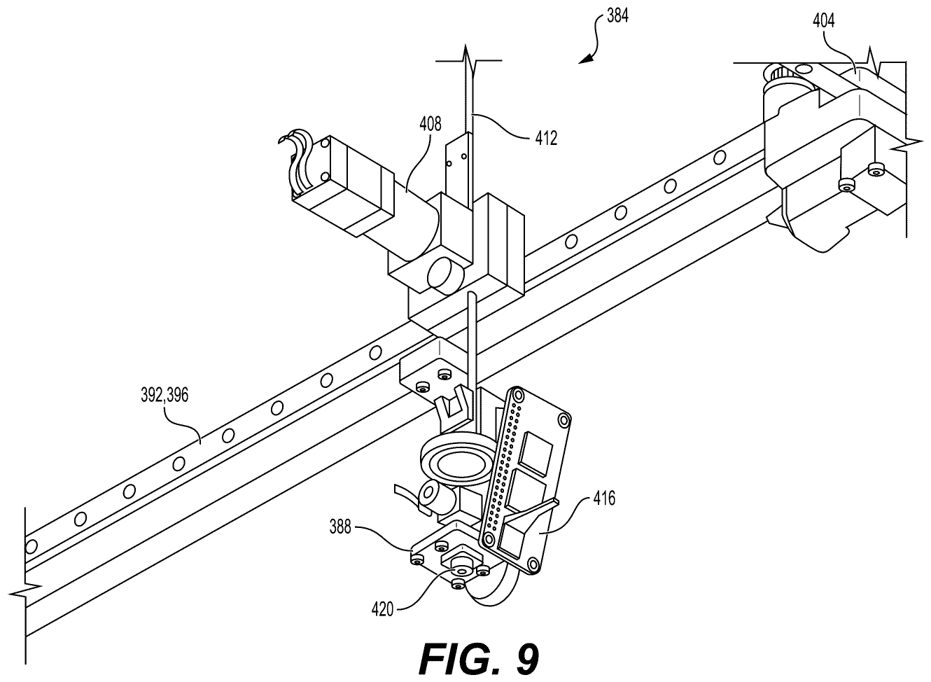

Referring now primarily to FIGS. 8 and 9, an illustrative camera system 384 of the illustrative work cell 104 will be described. Some embodiments of the work cell 104 may include the camera system 384. FIG. 8 presents an overview of the camera system 384, and FIG. 9 presents a detailed view of a portion of the camera system 384. The camera system 384 includes the camera 388 that may be moved around and may interact with other components of the work cell 104. The camera 388 may move in X, Y, and Z directions and may also have pitch and yaw movements, so that portions of the work cell 104 may be monitored using the camera 388.

The camera system 384 may include a plurality of camera-movement rails 392. A middle rail 396 may be moveably coupled to the side rails 400 with motorized gear units 404 that move the middle rail 392 in one direction. Another motorized gear unit 408 may be moved along the middle rail 392 to move the camera 388 along another direction. The camera 388 may be attached to a vertical post 412 that can be moved up or down by the motorized gear unit 408 to adjust the vertical height of the camera 388. The camera 388 may also be mounted to a moveable head 416 to allow for further adjustment of the angle and direction of view of the camera 388. The camera 388 has a lens 420 that may be a zoom lens to further allow detailed view or widescreen views.

In one embodiment, the camera 384 may provide a live stream to allow the user 128 to view the building or testing of an electronic device in real time or near real time. The system 100 or the camera system 384 may also incorporate augmented reality features that provide for characteristics of the system 100, components 142, or the electronic device to be assembled or tested to be displayed to the user 128 along with the live video stream. In some embodiments, the camera system 384 may be used to test functionality of electronic devices such as testing the colors of lights or testing movement of portions of the electronic devices being tested. In some embodiments, the camera system 384 may be used to read words or labeling on parts or on the components 142. In some embodiments, the camera system 384 may be used for optical guided placement of components 142. In some embodiments, the system 100 may relate actual visual images from the camera system 384 to electronic schematics. In some embodiments, the user 128 may be able to customize the functions of the camera 388. In some embodiments, the camera 388 may contain stereoscopic vision so the user 128 can view the work cell 104 from a three-dimensional video feed.

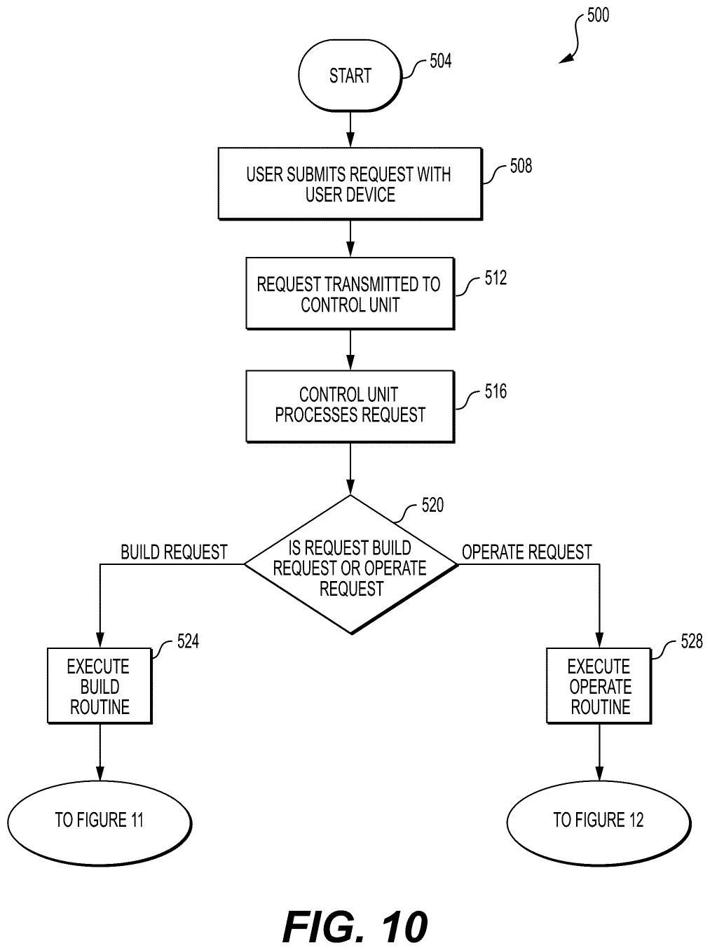

Referring now to FIGS. 10-12, and initially and primarily to FIG. 10, illustrative embodiments of methods utilizing the system 100 to build, prototype, or test electronic devices will be further discussed. Referring primarily to FIG. 10, a method 500 for building or operating electronic devices begins at step 504. At step 508, the user 128 inputs a request utilizing the user device 130. The user 128 may submit a build request or an operate request. The user 128 may also submit a request that includes both a build request and an operate request. A build request is a request for the system 100 to assemble the electronic device. Such a request can be used to assemble the prototype of the electronic device. An operate request is a request for the system 100 to operate the electronic device, for the system 100 to perform test functions on the electronic device, for the system 100 to provide some other input function into the electronic device, and the like. Operate requests may be used by the user 128 to test the functionality of the electronic device that has been assembled by the system 100.

A build request may include, for example, the various components 142 of the electronic device that the user 128 desires to build along with the connectivity instructions between the components 142. In some embodiments, the user 128 may be able to construct a virtual version of the device using a graphical user interface and to submit a completed virtual version of the device for assembly. In some embodiments, the users 128 may be able to layout or upload an electronic schematic of the electronic device to generate the build request. In some embodiments, a log data is created and saved from the work cell's operation during the build request. The data log may will be stored by the control unit 116, and be used to track work cell 104 statuses, e.g., for periodic maintenance, recommended calibration intervals, etc.

An operate request may include the operation of any functionality of the specific electronic device to be tested. In some embodiments, the control unit 116 may log output data, at least temporarily, to provide a backup for users 128.

At step 512, the request that was submitted by the user 128 with the user device 130 is transmitted to the control unit 116 using the network connection 124. In this manner, a user 128 can access and utilize the system 100 remotely.

At step 516, the control unit 116 processes the request to determine the appropriate action to take in response to receiving the request. Processing the request at step 516 may include, for example, verifying a user identity, verifying a user account associated with the user, verifying that the user account has sufficient funds to perform the request, verifying the validity of the request, etc., and the like, to name a few.

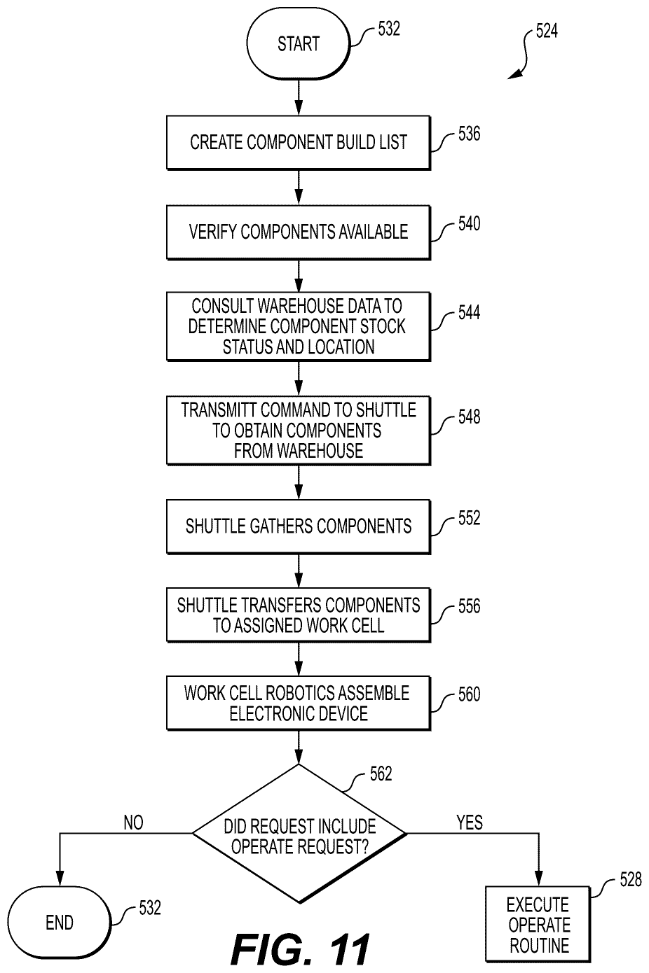

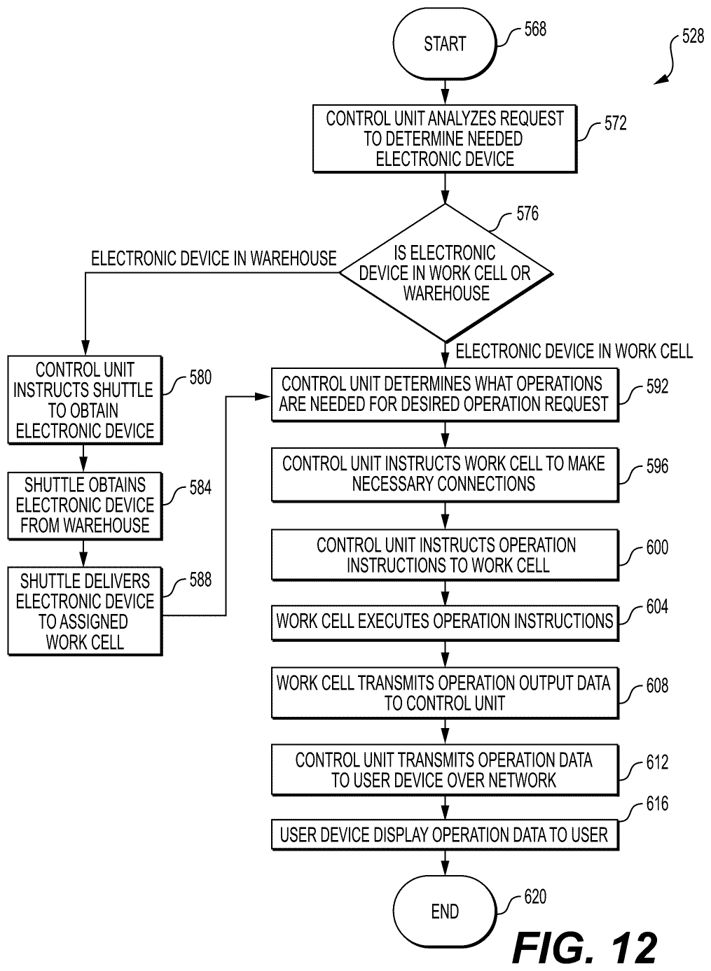

At step 520, the control unit 116 makes a determination as to whether the request is a build request or an operate request or both a build request and an operate request. If the control unit 116 determines that the request is a build request or a build and operate request, the method proceeds to step 524. If both build and operate are requested, the build portion is acted upon initially at step 524. At step 524, the control unit 116 executes a build routine. An illustrative embodiment of a build routine is depicted in FIG. 11. If the control unit 116 determines that the request is an operate request, then the method proceeds to step 528. At step 528, the system 100 executes an operate routine. An illustrative embodiment of an operate routine is depicted in FIG. 12.

Referring now primarily to FIG. 11, an illustrative embodiment of the build routine 524 will be described. The routine begins at step 532. At step 536 the control unit 116 utilizes data associated with the build request to create a list of components 142 that are required to build the electronic device. At step 540, the control unit 116 verifies that the required components 142 are components 142 that are associated with the system 100. In the case where the electronic device includes private components 144, the control unit 116 may execute routines to verify that the user 128 has authorization to access the private components 144.

At step 544, the control unit accesses warehouse data 131, which may be stored in database 135 (FIG. 2) to determine the locations of the required components 142 within the warehouse 108.

At step 548, the control unit 116 transmits commands to the shuttle 112 to obtain the required components 142. Such commands may include, for example, data indicating the location of each component 142 within the warehouse 108 or on the tray, the number of each component 142 required, etc.

At step 552, the shuttle 112 gathers the required components from the warehouse 108, and, at step 556, the shuttle 112 delivers the required components 142 to the work cell 104 assigned to build the electronic device. At step 560 the work cell 104 executes instructions received from the control unit 116 to robotically assemble the electronic device.

At step 562, the control unit 116 makes a determination as to whether the build request does or does not also include an operate request. If the build request does not include an operate request, the routine proceeds to step 564, where the routine ends. If the build request does include an operate request, the execute routine 528 is initiated.

Referring now primarily to FIG. 12, an illustrative embodiment of an operate routine 528 will be described. The operate routine begins at step 568. At step 572, the control unit 116 analyzes the operate request to identify the electronic device to which the operation request applies.

At step 576, the control unit 116 makes a determination as to the location of the electronic device to which the operate request applies. If the electronic device is located in a work cell 104, the routine proceeds to step 592. If the electronic device is located within the warehouse 108, the process proceeds to step 580. At step 580, the control unit 116 transmits instructions and any required data to the shuttle 112 instructing the shuttle 112 to obtain the electronic device from the warehouse 108. At step 584, the shuttle 112 collects the required electronic device from the warehouse 108. At step 588, the shuttle unit delivers the required electronic device to the assigned work cell 104.

Once the required electronic device is located within the work cell, the process continues at step 592. At step 592, the control unit 116 processes the operate request to determine what types of operations are needed to perform the request.

At step 596 the control unit 116 analyzes the operate request to determine what types of connections to the electronic device are needed to perform the desired operation and transmits instructions to the work cell 104 to make such connections. For example, an operation may require the system 100 to make power connections, network connections, data connections, etc, and the like, to the electronic device to perform the requested operation. The type and number of connections will vary based on the particular operations requested.

At step 600, based on the types of operations are needed to perform the request, the control unit 116 transmits instructions to the work cell 104 to perform the operation request. At step 604, the work cell 104 executes the instructions, which results in performance of the operation.

At step 608, the work cell 104 transmits operation output data to the control unit 116. The nature of the operation output data may vary and is dependent on the specific operation that the user 128 has requested. Some examples of possible operations include powering up the electronic device and uploading firmware into the electronic device to test the circuit and to interact with the electronic device. Operations may include executing test script procedures to test out portions of the electronic device. Operations may also include use of heat ovens, cooling ovens, humidity ovens, drop tests, pitch/yaw/role tilt, infrared FLIR cameras, test motors, test sensors, or other test accessories that facilitate testing the prototype of the electronic device.

At step 612, the control unit 116 transmits the operation output data to the user device 130 over the network 124. At step 616, the user device 130 displays the operation output data to the user 128 to provide the results of the operation request to the user 128. The operate routine ends at step 620 once all operations are completed. In some embodiments, operation output data is transmitted continuously in real time or near real time.

It should be understood that for the above described methods and routines, that not all steps of the methods or routines need to be performed. In addition, other steps may be performed. In addition, the steps may be performed in other orders than as described above. In addition, some steps or sets of steps may be repeated to achieve the desired electronic device or set of operations.

It should be appreciated that, while the above described methods and routines contemplate certain portions of the system 100 performing certain processes or actions, in other embodiments, portions of the system 100 other than those described above may perform those processes or actions. For example, in relation to the method 500, build routine 524, or operate routine 528, an process or analysis that is described as being performed by the control unit 116 may, in other embodiments, be performed by other components of the system 100. For example, the work cell 104 or the user device 130 may be used to process build or operate requests instead of such requests being processed by the control unit 116.

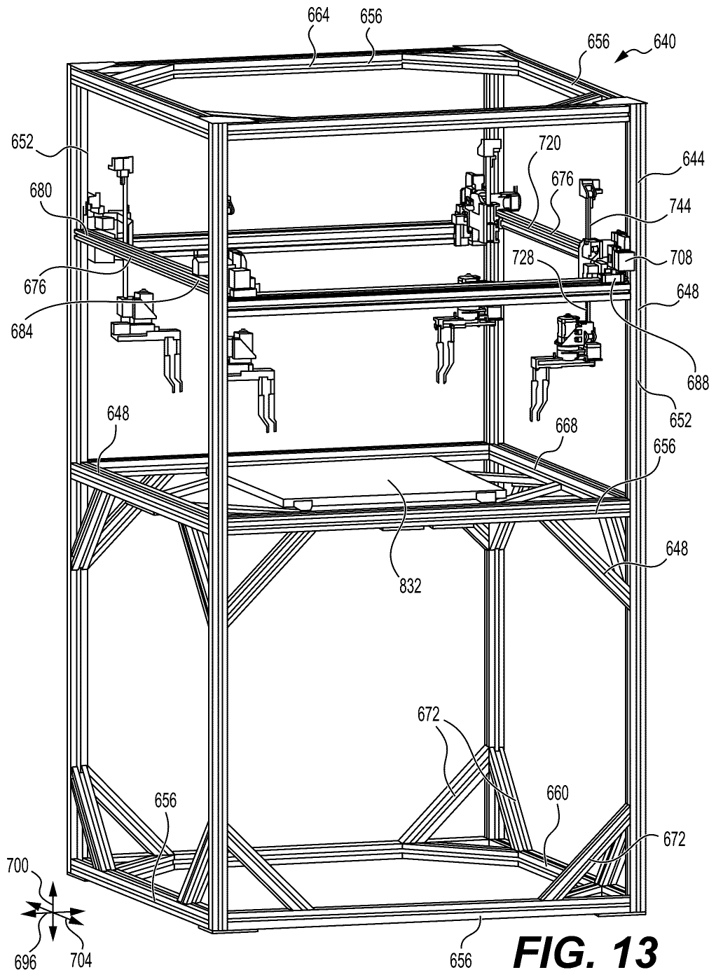

Referring now to FIGS. 13-18, an initially to FIG. 13, an illustrative embodiment of a work cell 640 will be discussed. The work cell 640 includes a framework 644 made from a plurality of support beams 648. Each of the plurality of support beams 648 are assembled and interconnected to form the framework 644. The plurality of support beams 648 includes upright supports 652 and cross beam supports 656. The cross beam supports 656 are coupled to the upright supports 652 so that the framework 644 has a cuboid shape with cross beam supports 656 forming a work cell base 660 and a top frame 664. Cross beam supports 656 are also coupled to the upright supports 652 to form a scaffold support 668. The plurality of support beams 648 may also include angle supports 672 coupled between at least some of the cross beam supports 656 and upright supports 652 to improve the stability and rigidity of the framework 644. In some embodiments, the framework 644 has a length of about 1 meter, a width of about 1 meter, and a height of about 2 meters. In some embodiments, the scaffold support 668 has a height of about 1 meter.

The work cell 640 also includes at least one pincer support assembly 676. In the illustrative embodiment of FIG. 13, there are two pincer support assemblies 676, each of which is coupled proximate to a first end 680 and a second end 684 of the pincer support assembly 676 to cross beam supports 656. Other embodiments may have other numbers of pincer support assemblies 676 or the pincer support assemblies 676 may be coupled to the framework 644 in other manners. For example, the pincer support assembly 676 may be coupled to only one cross beam support 656.

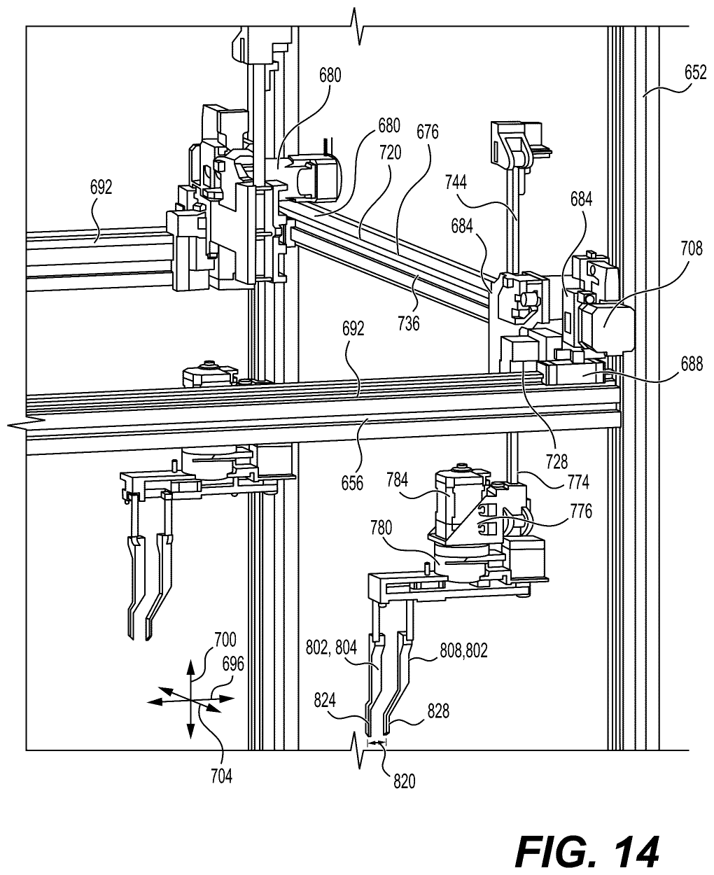

Referring now primarily to FIG. 14, the illustrative pincer support assembly 676 of the work cell 640 will be more fully described. The first end 680 and the second end 684 of the pincer support assemblies 676 are slidably coupled to the cross beam supports 656 so that the pincer support assembly 676 may translate along the length of cross beam supports 656. A slide member 688 of the pincer support assembly 676 is configured to mate with and conform to rails 692 that run along the length of the cross beam supports 656. The slide member 688 is therefore captured by the rails 692 while allowing the slide member 688 to translate in a direction 696, in the orientation shown.

The slide member 688 is couple to a drive unit 708. The drive unit 708 includes an electric motor 712 coupled to rollers 716. The electric motor 712 may be actuated to cause the rollers 716 to turn and engage with the cross beam support 656, which results in the pincer support assembly 676 translating back or forth along the cross beam support 656 along the direction 696 depending on which direction the electric motor 712, and therefore, the rollers 716 are turning. A person skilled in the art will appreciate that other methods may be used to drive the pincer support assembly 676 along the length of the cross beam support 656, for example, a rack and pinion or belt drive may be used.

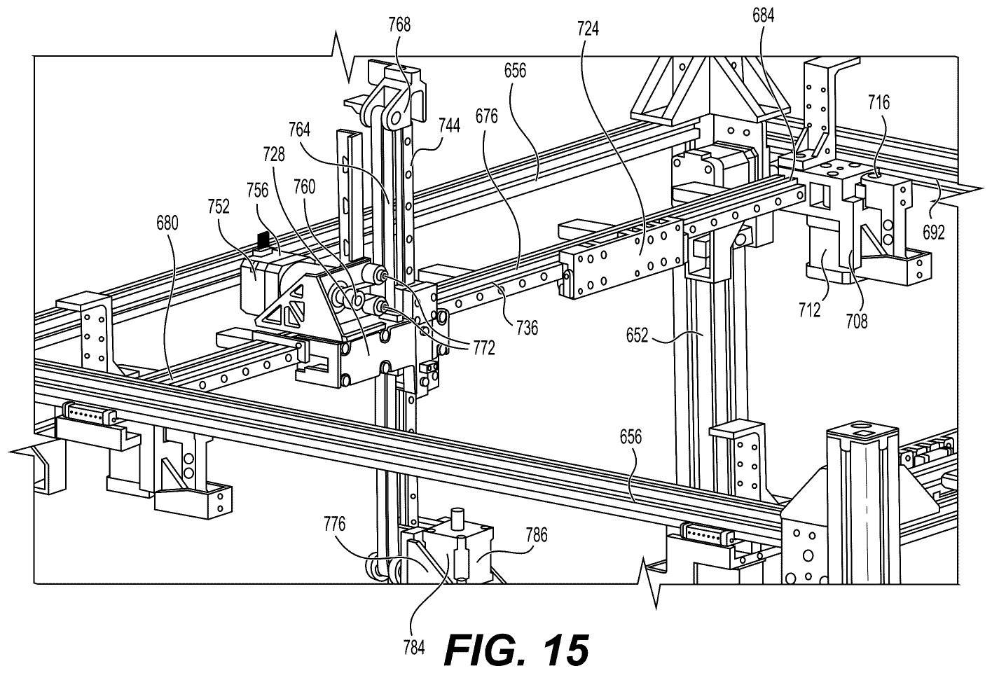

The pincer support is coupled to the drive unit 708 and slider member 688. At least one pincer mounting pad 724 (FIG. 15) for mounting a pincer subassembly 728 is coupled to the pincer support beam 720. In FIG. 15 one pincer mounting pad 724 is shown without the pincer subassembly 728 mounted to the pincer mounting pad 724, for clarity. The pincer mounting pad 724 is slidably coupled to the pincer support beam 720 to allow the pincer subassembly 728 to slide along the pincer support beam 720 in the direction 704 using the rail portion 736 of the pincer support beam 720.

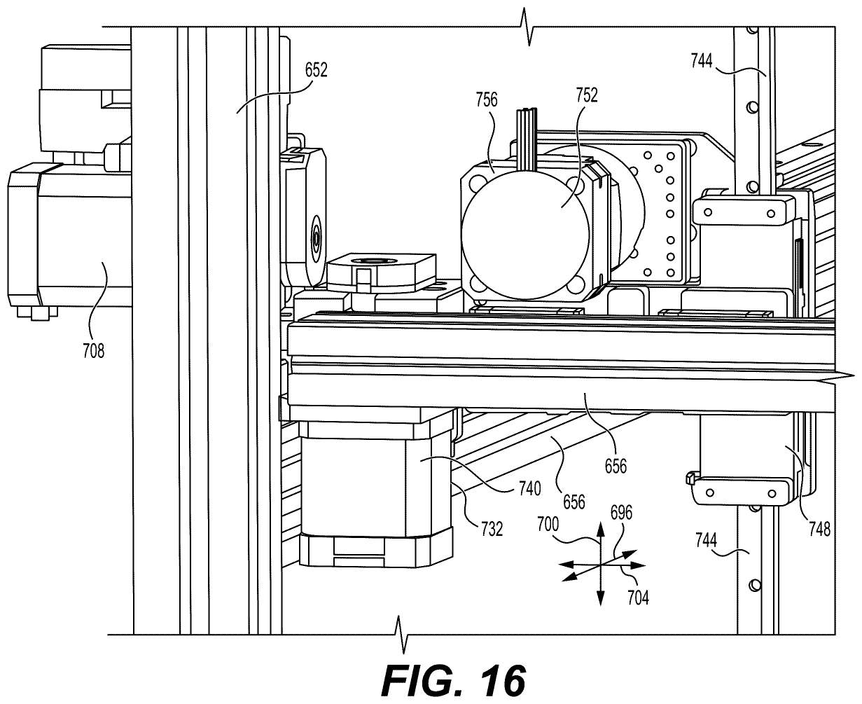

A drive unit 732 (FIG. 16) is coupled to the pincer mounting pad 724 and engages with the pincer support beam 720 or the rail portion 736 of the pincer support beam 720. The drive unit 732 includes an electric motor 740, such as a step motor, to power movement of the pincer subassembly 728 along the pincer support beam 720.

The pincer subassembly 728 includes a pincer riser bar 744 slidably coupled to the pincer mounting pad 724 by a mounting bracket 748 (FIG. 16). The slidable coupling between the pincer riser bar 744 and the pincer mounting pad 724 allows for the pincer riser bar 744 to be raised or lowered (as oriented in the figures) in the direction 700. A drive unit 752 (FIG. 16) is coupled to the pincer mounting pad 724 and is used to control movement of the pincer riser bar 744 in the direction 700.

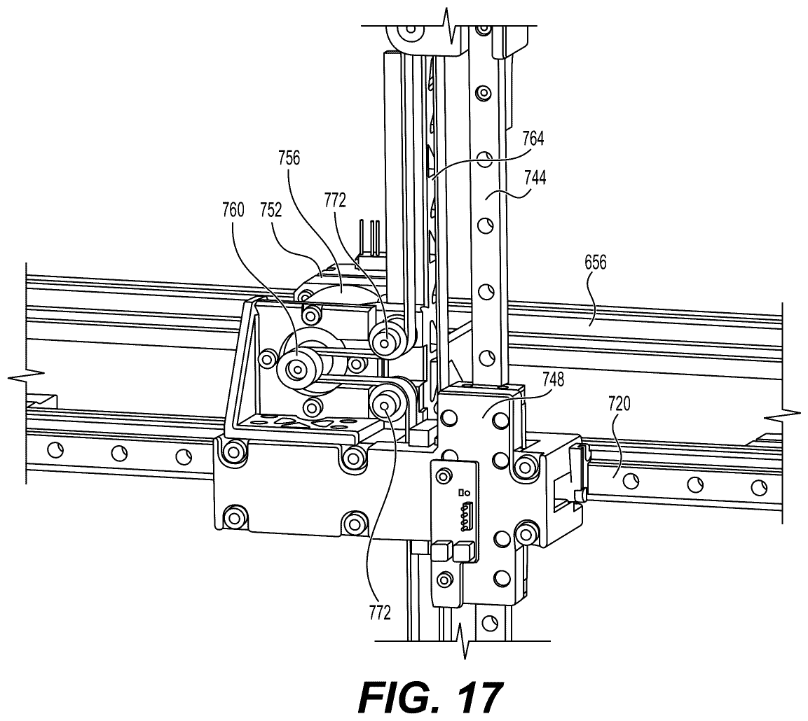

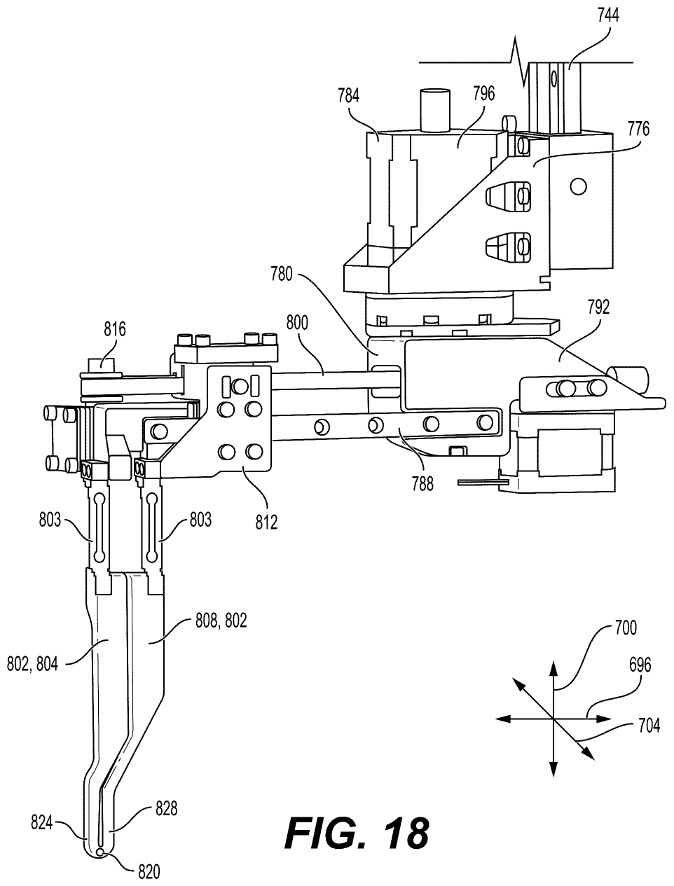

The drive unit 752 includes an electric motor 756, such as a stepper motor. A drive pully 760 (FIG. 15) is coupled to the electric motor 756. The drive pulley 760 engages a drive belt 764. The drive belt 764 is routed through a plurality of bearings 772 (FIG. 17), a top bracket 768 (FIG. 15) mounted to the pincer riser bar 744. and a bottom bracket 776 (FIG. 18) mounted to the pincer riser bar 744. Operation of the electric motor 756 results in driving the drive belt 764 along its route, which in turn results in the raising or lowering of the pincer riser bar 744 according to operation of the electric motor 756. The direction of movement of the pincer riser bar 744 along the direction 700 may be varied by varying the direction of operation of the electric motor 756.

Now referring primarily to FIG. 18, the bottom bracket 776 is coupled to a pincer head assembly 780. The pincer head assembly 780 includes a drive unit 784 coupled to a pincer slider bar 788 and a bracket 792. The drive unit 784 includes an electric motor 796 coupled to a pincer drive belt 800.

A stationary pincer arm 804 and a moveable pincer arm 808 are coupled to the pincer slider bar 788. The moveable pincer arm 808 is slidably coupled to the pincer slider bar 788 by slider bracket 812. The slider bracket 812 is coupled to the pincer slider bar 788 so that the slider bracket 812, and therefore, the moveable pincer arm 808 can translate along the pincer slider bar 788 in the direction 696.

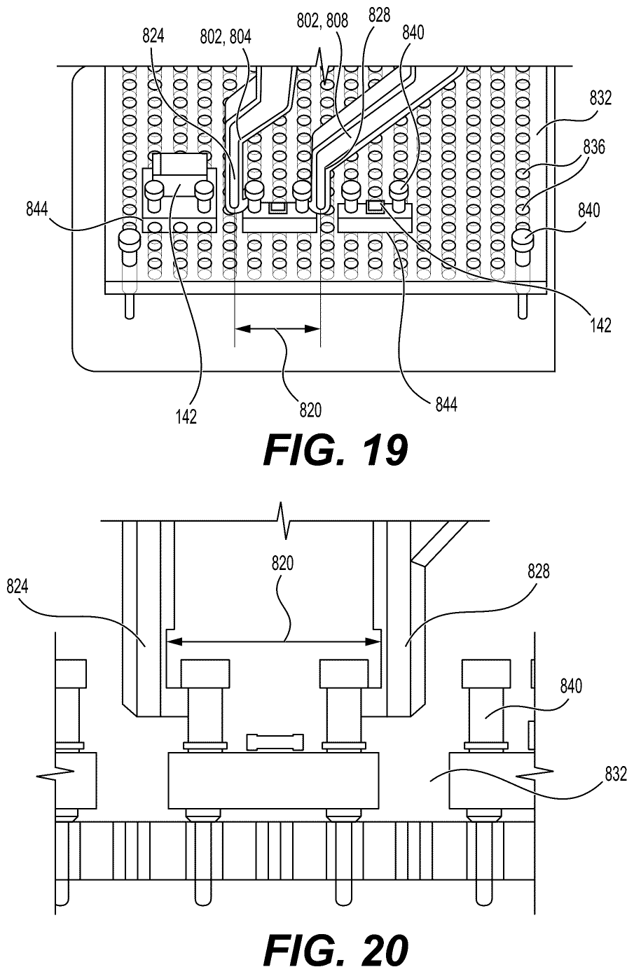

The pincer drive belt 800 is routed through a bearing 816 and is attached to the slider bracket 812. Since the pincer drive belt 800 is also engaged to electric motor 796 of the drive unit 784, operation of the electric motor 796 may be used to move the slider bracket 812 and, therefore, the moveable pincer arm 808 along the pincer slider bar 788 in the direction 696. The width of a pincer gap 820, which is a distance between a tip 824 of the stationary pincer arm 804 and a tip 828 of the moveable pincer arm 808, can be controlled by actuation of the electric motor 796 in one direction of rotation or the opposite direction of rotation. In FIG. 18, the stationary pincer arm 804 and the moveable pincer arm 808 are depicted in a closed position so the pincer gap 820 is effectively zero. In FIG. 19, the pincer gap 820 is depicted with a larger pincer gap 820.

In this manner, the electric motor 796 can be used to open and close the pincer gap 820 so that the stationary pincer arm 804 and the moveable pincer arm 808 may be used to couple to objects, move or manipulate the objects, and release the objects (as further described below).

Referring now to FIG. 19, an illustrative embodiment of a scaffold technique of the work cell 640 will be further described. Electronic devices are assembled within the work cell 640 utilizing the scaffolding technique. The scaffolding technique uses a series of scaffold bases 832 to hold components such as electronic components 142. The scaffold bases may be formed from a rigid material, such as a plastic or polymer or composite, to form a flat surface to use as a work space. The scaffold bases 832 may be in a variety of shapes and sizes. The scaffold bases 832 may also include a pattern of holes or slots for connecting or retaining various components 142.

The illustrative embodiment of FIG. 19 depicts a scaffold base 832 having a grid pattern of machine pin holes 836. Machine pins 840 may be used in conjunction with the machine pin holes 836 to retain components 142 onto the scaffold base 832. In FIG. 19 three electronic components 142 are shown installed onto the scaffold base 832. Each electronic component 142 has a component base 844. The component base 844 has machine pin holes 836 with spacing that corresponds to the machine hole pins 836 of the scaffold base 832. The electronic component 142 is placed onto the scaffold base 832 so that the machine pin holes 836 of the component base 844 align with the machine pin holes 836 of the scaffold base 832. The machine pins 840 are inserted into the machine pin holes 836 to retain the electronic component 142 onto the scaffold base 832. FIG. 20 depicts a side view of a portion of a scaffold base 832 with electronic components 142 mounted onto the scaffold base 832 with machine pins 840.

The placement of electronic components 142 and other components, such as wires to connect electronic components 142 is achieved utilizing the pincer head assembly 780 described in relation to FIGS. 13-18

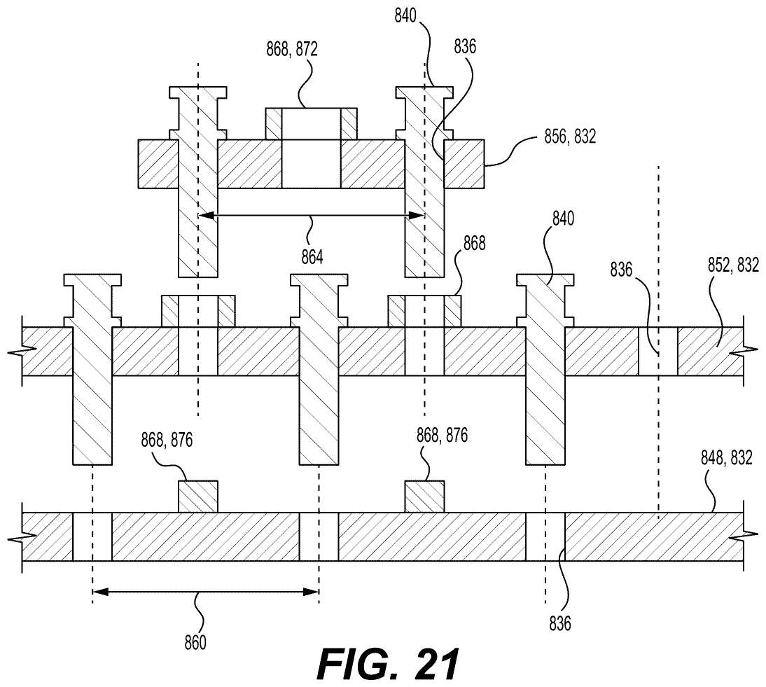

Machine pins 840 may be used in conjunction with the machine pin holes 836 to also retain the scaffold base 832 onto another scaffold base 832. In this manner, scaffold bases 832 may be stacked on top of each other to facilitate assembly of electronic devices. FIG. 21 illustrates the alignment and process for stacking multiple scaffold bases 832. For illustrative purposes three scaffold bases 832, which are a first scaffold base 848, second scaffold base 852, and third scaffold base 856, are depicted. As shown, each of the scaffold bases 832 has a number of machine pin holes 836 through which machine pins 840 may be inserted. The machine pin holes 836 are spaced from each other by a distance 860. In this manner, the machine pin hole 836 of the first scaffold base 848 may be aligned with the machine pin holes 836 of the second scaffold base 852. Likewise, machine pins holes 836 of the second scaffold base 852 and machine pine holes 836 of the third scaffold base 856 may be spaced from each other by a distance 864 to facilitate installing the third scaffold base 856 onto the top of the second scaffold base 852. The distance 860 need not be the same length as the distance 864. Some scaffold bases may include machine pin holes that are spaced apart from each other at different distances to facilitate coupling of the scaffold bases 832 to other scaffold bases 832, electrical components 142, or other components. In some embodiments, the scaffold bases 832 may include standoffs 868 to facilitate the a desired stacking height between stacked scaffold bases 832. The standoffs 868 may be associated with or surround machine pins holes 836, such as is shown for standoffs 872 or may be not associated with machine pin holes 836, such as standoffs 876.

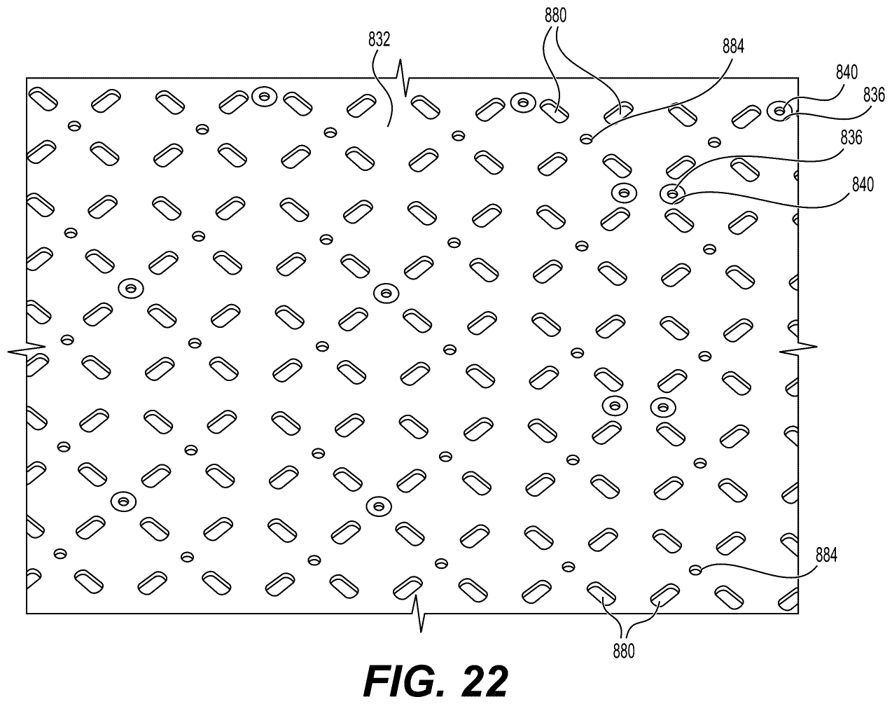

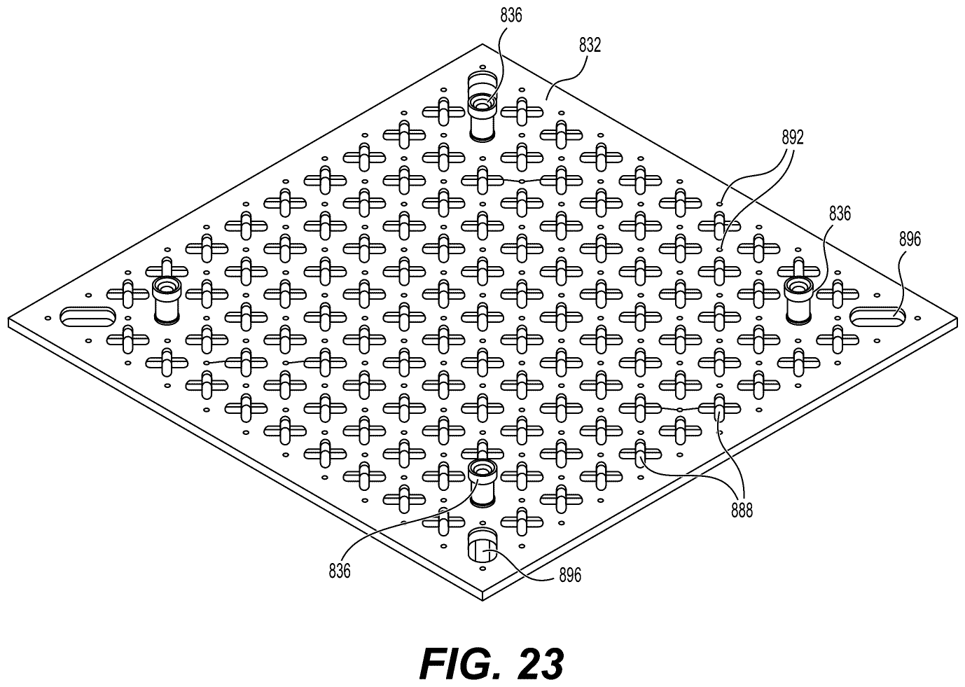

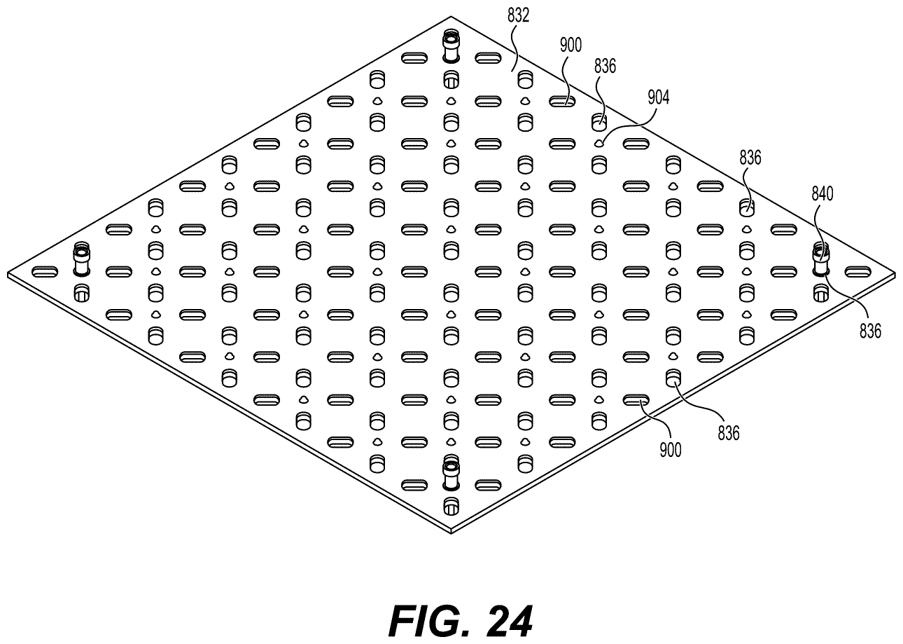

Referring now to FIGS. 22-24, some illustrative embodiments of scaffold bases 832 will be discussed. Scaffold bases 832 may use any number of holes, openings, or slots to assemble components to the scaffold bases 832 and to couple stacked scaffold bases 836. FIG. 22 depicts a portion of a scaffold base 832 that includes a geometric repeated pattern of four slots 880 arranged in an angular pattern around a mounting or alignment hole 884. The scaffold base 832 of FIG. 22 also includes a number of machine pins 840 inserted into machine pin holes 836, as described above. The scaffold base 832 of FIG. 23 includes cross shaped slots 888 arranged in a repeating pattern along with mounting or pin holes 892. The scaffold base 832 of FIG. 23 also includes slots 896 located the corners of the scaffold base 832 and machine pins 836. The scaffold base 832 of FIG. 24 includes a repeating geometric pattern of slots 900, mounting or pin holes 904, and machine pins holes 836. The scaffold base 832 of FIG. 24 also includes machine pins 840 installed in machine pin holes 836 proximate each corner of the scaffold base 832. In some embodiments the repeating geometric pattern in FIGS. 22 and 24 has a spacing of about 32 mm between repeating features, and the pitch of the embodiment of FIG. 23 is about 8 mm. Other spacings and pitches may be used. In some embodiments, a large scaffold base 832 has spacing of machine pin holes 836 or other openings spaced from each other in the range of 6-10 mm, a medium scaffold base 832 has spacing of machine pin holes 836 or other openings spaced from each other in the range of 6-10 mm, and a small scaffold base 832 has spacing of machine pin holes 836 or other openings spaced from each other in the range of 0.5-2 mm. In some embodiments the spacing between machine pin holes 836 or other openings spaced from each other in the large scaffold base 832 is 9 mm. In some embodiments the spacing between machine pin holes 836 or other openings spaced from each other in the medium scaffold base 832 is 2 mm. In some embodiments the spacing between machine pin holes 836 or other openings spaced from each other in the small scaffold base 832 is 1 mm.

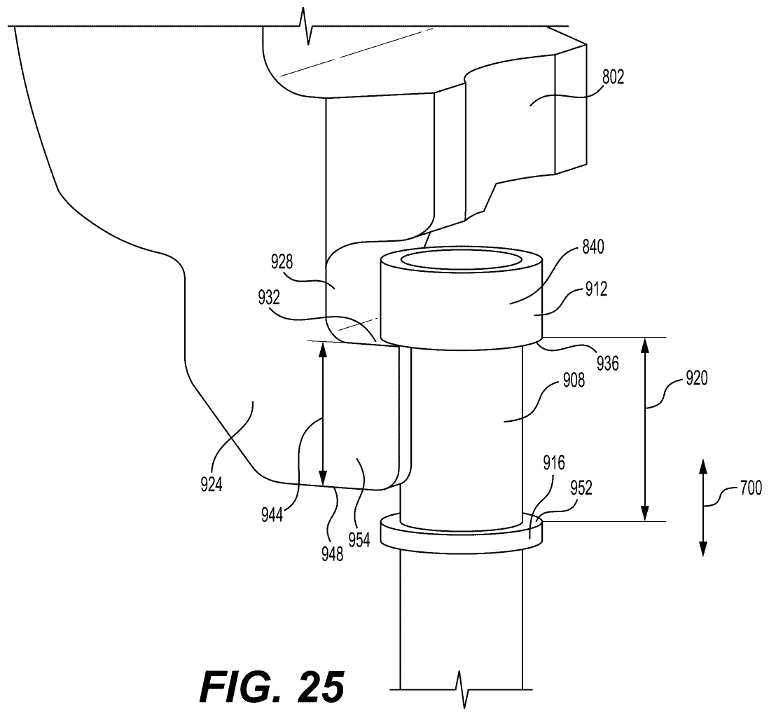

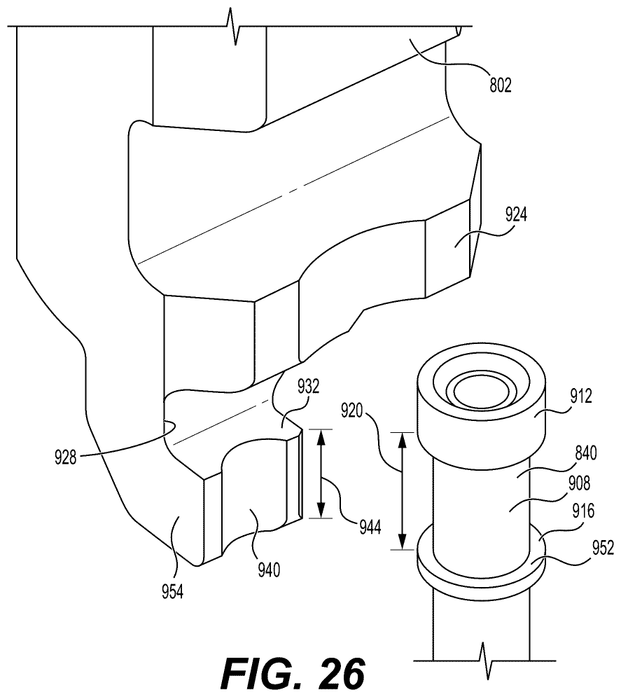

Referring now to FIGS. 25 and 26, the interaction between the pincer arm 802 and the machine pins 840 will be further discussed. The machine pins 840 have a cylindrical body 908. A first ridge 912 is formed on the upper end of the cylindrical body 908. A second ridge 916 is formed on the cylindrical body 908 a distance 920 from the first ridge 912. A pincer tip 924, which may be the tip 824 of the stationary pincer arm 804 or tip 828 of the moveable pincer arm 808 as described above, is sized and configured to mate with the cylindrical body 908, first ridge 912, and second ridge 916 of the machine pin 840. The pincer tip 924 is formed with a cutout 928 to form a mating surface 932. When the pincer tip 924 engages with the machine pin 840, the mating surface 932 contacts a lower surface 936 of the first ridge 912 of the machine pin 840. The cutout 928 of the pincer tip 924 is sized and configured so that the first ridge 912 of the machine pin 840 fits within the cutout 928.

The pincer tip has cutout 940, which is shaped and sized to conform to the cylindrical body 908 of the pincer tip 924 when the pincer tip 924 engages the machine pin 840.

The pincer tip 924 has a distance 944 between the mating surface 932 and a lower surface 948. The distance 944 is greater than the distance 920 (between the first ridge 912 and the second ridge 916, so that when the pincer tip 924 engages with the machine pin 840, a lower block 954 of the pincer tip 924 fits in the distance 920 between the first ridge 912 and the second ridge 916 of the machine pin 840, as shown in FIG. 25.

Using this configuration, the pincer tip 924 of the pincer arm 802 can be used to manipulate and move machine pins 840 and, therefore, any other component coupled to the machine pins 840, such as the electronic component 142 or scaffold base 832. To do so, a pincer tip 924 is maneuvered into place so that the first ridge 912 and the second ridge 916 of the machine pin 840 are located between the mating surface 932 and lower surface 948 of the pincer tip 924 and so the cylindrical body 908 of the machine pin 840 is mated to and conforms with the cutout 940 of the pincer tip 924, as shown in FIG. 25.

In this position, the pincer tip 924 can be used to pick up the machine pin 840. By moving the pincer tip 924 upward (as depicted) in the direction 700, the mating surface 932 of the pincer tip 924 contacts and engages with the lower surface 936 of the first ridge 912 of the machine pin 840 to lift the machine pin 840. Conversely, by moving the pincer tip 924 downward in the direction 700, the lower surface 948 of the pincer tip 924 contacts and engages with a top surface 952 of the second ridge 916 of machine pins 840 to push the machine pins 840 downward into machine pin holes 836 (FIG. 20).

Since the scaffold bases 832 and the electronic components 142 include machine pins 840, the pincer tips 924 may be used to manipulate the scaffold bases 832 and electronic components 142 to lift, drop, move, install, etc. the scaffold bases 832 and electronic components 142. In this manner, the work cell 640 may be used to assemble electronic devices for testing or prototyping.

In some embodiments, a single pincer arm 802 may be used to manipulate machine pins 840. In other embodiments, a pair of pincer arms 802 work in conjunction to manipulate machine pins 840, such as is depicted in FIGS. 19 and 20. In FIGS. 19 and 20, the pincer arms 802 are engaging with and able to lift and move the electrical component 142 by engaging one pincer tip 924 with each of two machine pins 840 that are mounted into the component base 844 of the electrical component 142.

As described above, the pincer arms 802 may also be part of the shuttle 112 or part of the warehouse 108 and may be used to manipulate electrical components that are stored in the warehouse 108 and that are being delivered by the shuttle 112 to the work cell 104 or to the warehouse 108.

In some embodiments, the pincer head assembly 780 (FIG. 18) includes a sensor for sensing the pressure exerted between two pincer arms 802 (such as the stationary pincer arm 804 and the moveable pincer arm 808 as shown in FIG. 18) to determine the amount of interaction between two pincer arms 802 and the machine pins 840 of a component that the pincer arms 802 are manipulating. In some embodiments, the sensing interaction includes determining the amount of deflection of one or more pincer arms 802 while the pincer arms 802 engage machine pins 840. In some embodiments, the pincer arms 803 include pincer deflectors 803, which may be used to determine the amount of deflection of the pincer arms 802 when the pincer arms 802 are used to grab a component.

In some embodiments, the pincer head assembly 780 also includes a motor and drive for rotating the pincer arms on an axis. In some embodiments, the pincer arms may be rotated around an axis that is oriented in the direction 700, as shown.

A person skilled in the art will appreciate that other mating configurations between the pincer arm tips 924 and the machine pins 840 may be used to engage the pincer arm tips 924 and the machine pins 840 to manipulate the machine pins 840. A person skilled in the art will appreciate that the pincer arms 802 may be designed to engage with and manipulate other items or components other than machine pins 840.

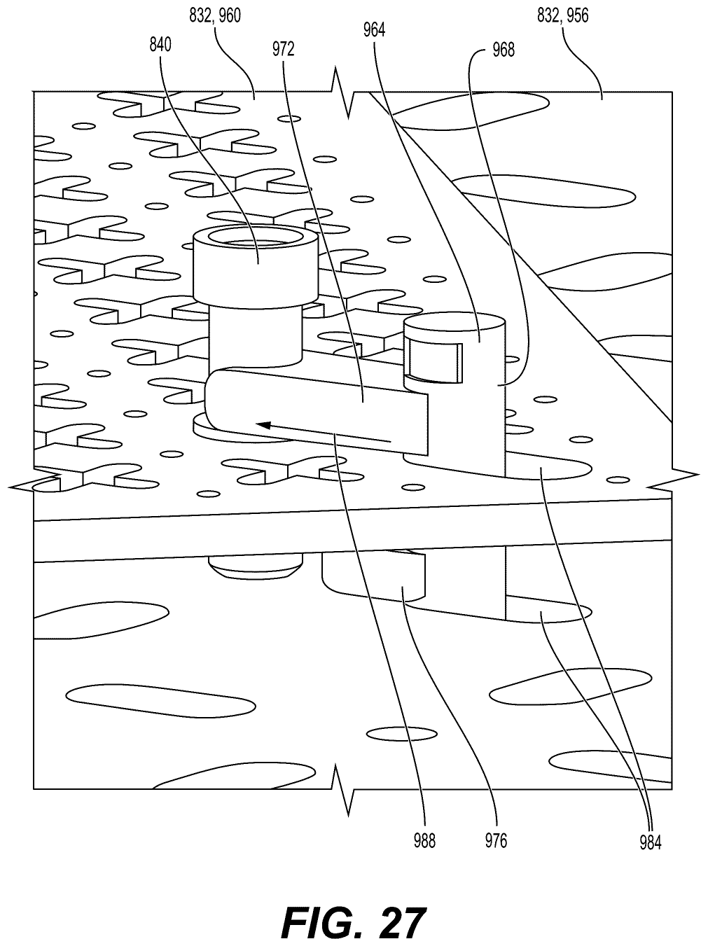

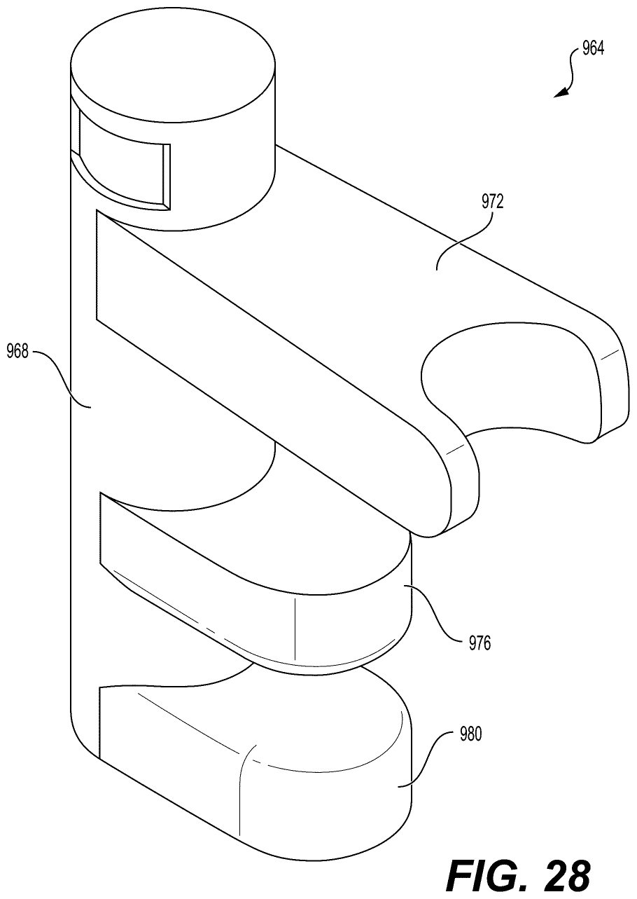

Now referring to FIGS. 27 and 28, additional aspects of the scaffolding technique used by the work cell 640 to assemble electronic devices will be discussed. As discussed above in relation to FIGS. 19-21, scaffold bases 832 may be stacked on top of one another when electronic devices are assembled by the work cell 640. FIG. 27 depicts an illustrative embodiment of this technique. Two scaffold bases 832 are depicted, which are a lower scaffold base 956 and an upper scaffold base 960. As discussed in relation to FIGS. 19-21, the upper scaffold base 960 includes machine pins 840 mounted proximate to the corners of the upper scaffold base 960. The upper scaffold base 960 has been installed onto and above of the lower scaffold base 956 by inserting the machine pins 840 of the upper scaffold base 960 into mating machine pin holes 836 of the lower scaffold base 956. A scaffold retaining clip 964. is utilized to further retain the upper scaffold base 960 to the lower scaffold base 956.

The illustrative embodiment of the scaffold retaining clip 964 of FIGS. 27 and 28 has a cylindrical body 968. An upper tab 972, middle tab 976, and lower tab 980 extend from the cylindrical body 968 of the scaffold retaining clip 964. The upper tab 972, middle tab 976, and lower tab 980 are sized and configured to mate with and interact with the stacked scaffold bases 832 to aid in retaining the stacked scaffold bases. As can be seen in FIG. 27, both the upper scaffold base 960 and the lower scaffold base 956 have retaining clip slots 984 located proximate to the corners of the upper scaffold base 960 and the lower scaffold base 956.

The middle tab 976 and lower tab 980 of the scaffold retaining clip 964 are sized and configured to enter into the retaining clip slots 984. In this manner, the scaffold retaining clip 964 may be inserted in the retaining clip slots 984 so that the lower tab 980 is located below the lower scaffold base 956, the middle tab is located between the lower scaffold base 956 and the upper scaffold base 960, and the upper tab 972 is located above the upper scaffold base 960. In this position, the scaffold retaining clip 964 can be moved in direction 988 so that the upper tab 972, middle tab 976, and lower tab 980 engage with surfaces of the lower scaffold base 956 or upper scaffold base 960 to lock the scaffold bases 932 together. In addition, the upper tab 972 is sized and configured to mate with the machine pin 840 when installed in such a manner to increase the retaining effect of the scaffold retaining clip 964.

In some embodiments, the spacings between the upper tab 972, middle tab 976, and lower tab 980 and the lower scaffold base 956 or upper scaffold base 960 are sized and configured to provide an interference fit between the lower scaffold base 956, upper scaffold base 960, and scaffold retaining clip 964.

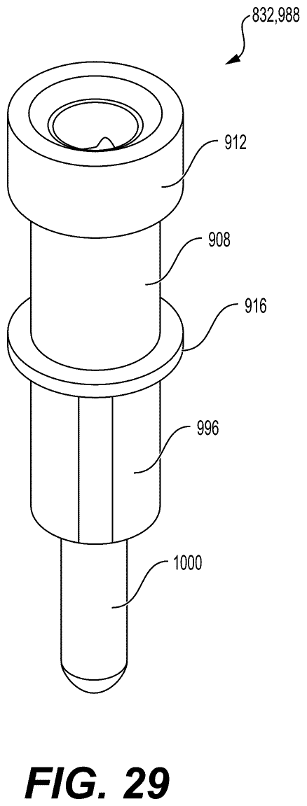

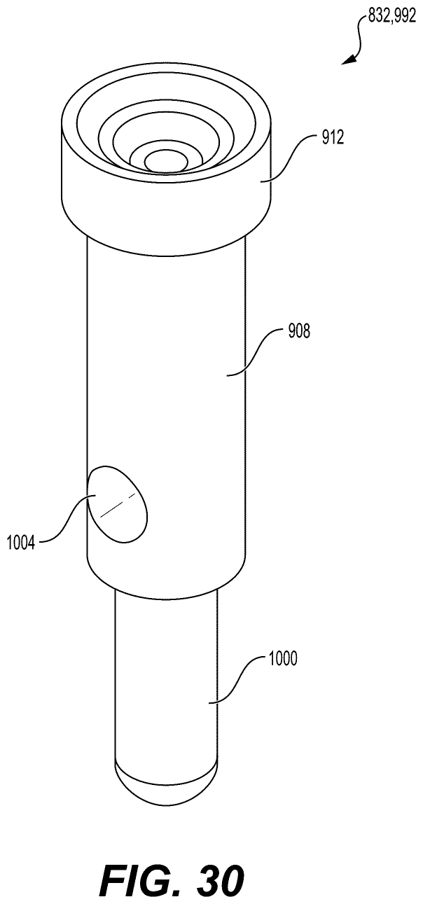

Now referring to FIGS. 29 and 30, additional aspects of illustrative embodiments of machine pins 840 will be discussed. Various types and designs of machine pins 840 may be used in the scaffolding technique of the work cell 640. FIG. 29 depicts an illustrative embodiment of an assembly machine pin 988. FIG. 30 depicts an illustrative embodiment of an electrical connection machine pin 992. The nomenclature of the assembly machine pin 988 and the electrical connection machine pin 992 is intended to be solely for descriptive purposes and should not be considered in a limiting sense as to the function of a particular machine pin 840. For example, an electrical connection machine pin 992 may be used to both provide assembly functions and electrical connection functions.

The assembly machine pin 988 of FIG. 29 includes the cylindrical body 908, first ridge 912, and second ridge 916 as discussed in relation to FIGS. 25 and 26 above. In addition, a retention portion 996 is shown in FIG. 29. The retention portion 996 of the assembly machine pin 988 is sized and configured to be inserted into and to mate with machine pins holes 836 (FIGS. 19 and 20). The retention portion 996 of some embodiments of the assembly machine pins 988 is sized and configured to provide an interference fit between the retention portions 996 and machine holes 836. A lower portion 1000 of the assembly machine pin 988 is sized and configured to mate with other sized machine pins holes 836 or other features of scaffold bases 832 such as mounting or pin holes 884, 892, 904 (FIGS. 22, 23, 24).

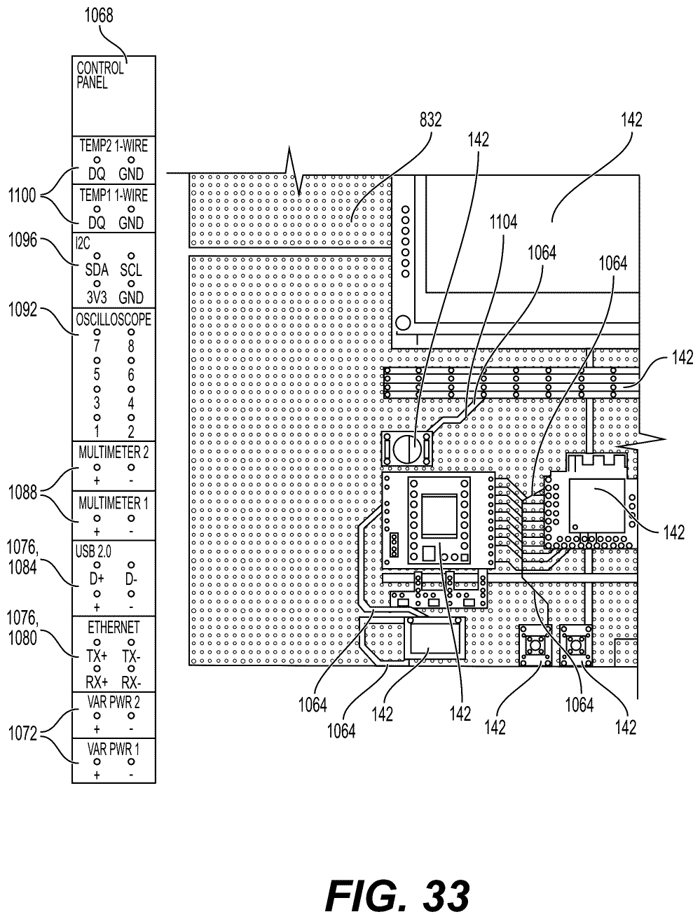

The electrical connection machine pin 992 of FIG. 30 has some analogous features as described in relation to the assembly machine pin 988 of FIG. 29 such as the cylindrical body 908, first ridge 912, and lower portion 1000. In addition, the electrical connection machine pin 992 has an electrical connection aperture 1004. The electrical connection opening 1004 may be utilized to make an electrical connection to the electrical connection machine pin 992 inserting a wire (FIG. 33) through the electrical connection aperture 1004. The electrical connection machine pin 992 is made from a conductive material such as stainless steel, to provide a further electrical connection between the wire and additional electrically conductive components in contact with the electrical connection machine pin 992.

It should be understood that other machine pins 840 may include different number of features or different combinations of features as described herein. For example, machine pins 840 may include additional ridges of various sizes to accommodate different levels of scaffold bases 832, scaffold bases 832 featuring variously sized and shaped opening, and different electrical component 142 configurations. The sizes and dimensions of machine pins 840 and their features may also vary to accommodate different assemblies of electronic devices. Machine pins 840 may include an aperture 1004 (FIG. 30), which may be used for soldering a wire to the machine pin 840 and thus enabling wired connections throughout the work cell 104. Different machine pins 840 may be used to address different geometric pattern spacings on the scaffold base 832. The diameters of machine pins 840 may be in the range of less than 1 mm to approximately 5 mm. Vertical lengths of machine pins 840 may be in the range of 5-20 mm.

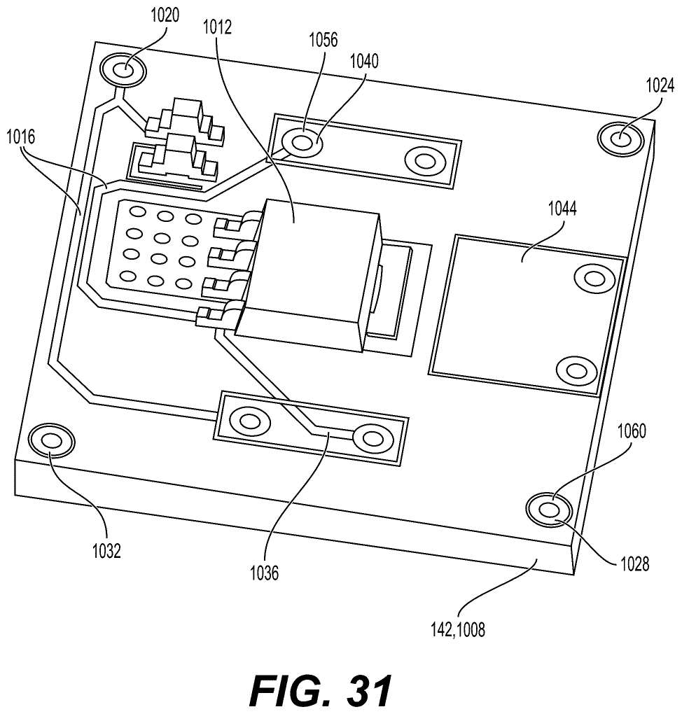

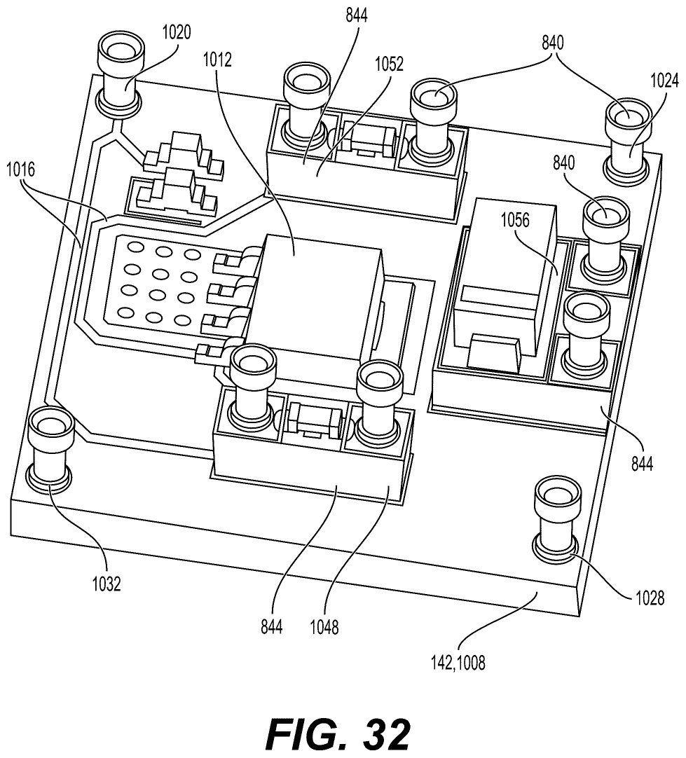

Referring now to FIGS. 31 and 32, additional aspects illustrative embodiments of the components 142 will be discussed. The components 142 are designed to be modular in nature to facilitate diversity in the types of electronic devices that may be assembled using the work cells 104 or work cells 640.

FIG. 31 depicts an illustrative component 142, which may be, for example, a test board 1008. The test board 1008 is a PCB that includes a chip 1012 electrically coupled by traces 1016 to other various components or features of the test board 1008. In the example test board 1008, the chip 1012 is electrically coupled to a gate 1020, a drain 1024, hv connection 1028, and a ground 1032. In addition, traces 1016 electrically couple a resistor slot R1 1036, a resistor slot R2 1040, and a diode slot 1044. In the test board 1008 of FIG. 31 the resistor slot R1 1036 and resistor slot R2 1040 do not include resistors and the diode slot 1044 does not include a diode. The test board 1008, without resistors or diode installed, may be stored in the warehouse 108 and be a component 142 available to the user 128 for design of the electronic device.

The user 128 may desire to incorporate the test board 1008 into an electronic prototype or may want to preform prototype testing on the chip 1012. However, the user 128 may desire to vary the resistors or diode used in the prototype or test. To facilitate the different possibilities that various users 128 may desire, resistors and diodes are among the components 142 stored in the warehouse 108 and available for use by a user 128.

In FIG. 32, the test board 1008 is depicted with a first resistor component 1048 installed in resistor slot R1 1036, a second resistor component 1052 installed in the resistor slot R2 1040, and a diode component 1056 installed in the diode slot 1044. As can be seen each of the first resistor component 1048, second resistor component 1052, and diode component 1056 are components 142 that are mounted onto component bases 844 and include machine pins 840. The machine pins 840 of the component bases 844 each align with and fit into the machine pin holes 836 of the test board 1008.

In addition to mechanically fixing the components 142 in place, the machine pins 840 may also establish electrical connections to the components 142. As seen in FIG. 31, the machine pin holes 836 are surrounded by a ring-shaped electrical connection 1060. When placed within the machine pin holes 836, the machine pins 840 make electrical connection to the ring-shaped electrical connection 1060 of the test board 1008. The machine pins 840 of the components 142 may be electrically coupled to the particular electronic component mounted to the component base 844 to continue the electrical circuit.

In this manner the user 128 can customize the test board 1008 to include any particular resistors or diodes available in the warehouse 108.

The gate 1020, drain 1024, hv connection 1028, and ground 1032 of the test board 1008 may be electrically coupled by the combination of wires and electrical connection machine pins 992 as described in relation to FIG. 30 to provide functionality to these features of the test board 1008. In addition, it should be understood that the test board 1008 is also a component 142 that may be used not only in a electrical device but that may, itself, be installed onto a different component 142 in the same manner that the first resistor component 1048, second resistor component 1048, and diode component 1056 were installed onto the test board 1008.

Referring now primarily to FIG. 33, further aspects of the work cell 640 and scaffold bases 832 will be discussed. FIG. 33 depicts an illustrative number of components 142 assembled onto a scaffold base 832. As described above, the components 142 may be assembled onto the scaffold base 832 and be electronically interconnected to form an electronic device for prototyping, design, or testing. As further discussed above, the components 142 may be any type of electronic component used in an electrical device. In the illustrative embodiment of FIG. 33, electrical connections between components 142 may be established utilizing pre-bent wires 1064.

The work cell 640 may also include a control board 1068. The control board 1068 may be used to provide relevant electrical connections to components 142. For example, the control board 1068 may include power connections 1072, which may supply AC or DC power. The power connections 1072 may provide variable power, and the power output may be set by the user 128. The control board 1068 may include communication or data connections 1076, such as ethernet connection 1080 or USB connection 1084. The control board 1068 may include multimeter connections 1088. The control board 1068 may include oscilloscope connections 1092. The control board 1068 may include 12C connection 1096. The control board 1068 may include temperature sensor connections 1100. The control board 1068 may also include an integrated processor capable of analyzing digital inputs and generating digital outputs through multiple GPIO connections. The integrated processor may also have access to peripheral devices such as an ADC and DAC with connections to analyze and generate analog signals.

A person of skill in the art will appreciate that the functionalities of the control board 1068 may be a varied to provide common connectivity, inputs, and outputs used by electronic devices and that the provided connection types are illustrative. Connections between the control board 1068 connections and the components 142 may be made using suitable pre-bent wires 1064.

The pre-bent wires 1064 may be made from any suitable electrically conductive material such as copper or stainless steel. The pre-bent wires 1064 may further be partially coated with an insulating layer 1104 with exposed electrically conductive material at each end for establishing a connection to the components 142. The pre-bent wires 1064 may be stored in the warehouse 108 for the user 128 to select during the design of electronic devices and may be manipulated by pincer arms 802 in the same manner as described in relation to the manipulation of components 142 and machine pins 840 utilizing pincer arms 802 to establish electrical connections in the electronic device or prototype.

In some embodiments, the work cells 104, 640 or the system 100, as described herein, may be utilized to remotely operate electronic device and for remotely viewing the operation of those electronic devices. As used herein, electronic device is not used in a limiting sense. An electronic device may be any assembly of electrically operated components, including subassemblies of electrically operated components. For example, the work cells 104, 640 or the system 100 may be used to mock up, operate, or demonstrate an electronic device such as a robotic arm, computer, tablet, or any other electronic device.

Possible context for the computer aspects in some embodiments are now presented. The present disclosure is described below with reference to block diagrams and operational illustrations of methods and devices. It is understood that each block of the block diagrams or operational illustrations, and combinations of blocks in the block diagrams or operational illustrations, can be implemented by means of analog or digital hardware and computer program instructions. These computer program instructions can be provided to a processor of a general-purpose computer to alter its function as detailed herein, a special purpose computer, ASIC, or other programmable data processing apparatus, such that the instructions, which execute via the processor of the computer or other programmable data processing apparatus, implement the functions/acts specified in the block diagrams or operational block or blocks. In some alternate implementations, the functions/acts noted in the blocks can occur out of the order noted in the operational illustrations. For example, two blocks shown in succession can in fact be executed substantially concurrently or the blocks can sometimes be executed in the reverse order, depending upon the functionality/acts involved.

These computer program instructions can be provided to a processor of a general purpose computer to alter its function to a special purpose; a special purpose computer; ASIC; or other programmable digital data processing apparatus, such that the instructions, which execute via the processor of the computer or other programmable data processing apparatus, implement the functions/acts specified in the block diagrams or operational block or blocks, thereby transforming their functionality in accordance with embodiments herein.

For the purposes of this disclosure a computer readable medium (or computer-readable storage medium/media) stores computer data, which data can include computer program code (or computer-executable instructions) that is executable by a computer, in machine readable form. By way of example, and not limitation, a computer readable medium may comprise computer readable storage media, for tangible or fixed storage of data, or communication media for transient interpretation of code-containing signals. Computer readable storage media, as used herein, refers to physical or tangible storage (as opposed to signals) and includes without limitation volatile and non-volatile, removable and non-removable media implemented in any method or technology for the tangible storage of information such as computer-readable instructions, data structures, program modules or other data. Computer readable storage media includes, but is not limited to, RAM, ROM, EPROM, EEPROM, flash memory or other solid state memory technology, CD-ROM, DVD, or other optical storage, magnetic cassettes, magnetic tape, magnetic disk storage or other magnetic storage devices, or any other physical or material medium which can be used to tangibly store the desired information or data or instructions and which can be accessed by a computer or processor.

For the purposes of this disclosure the term “server” should be understood to refer to a service point which provides processing, database, and communication facilities. By way of example, and not limitation, the term “server” can refer to a single, physical processor with associated communications and data storage and database facilities, or it can refer to a networked or clustered complex of processors and associated network and storage devices, as well as operating software and one or more database systems and application software that support the services provided by the server. Servers may vary widely in configuration or capabilities, but generally a server may include one or more central processing units and memory. A server may also include one or more mass storage devices, one or more power supplies, one or more wired or wireless network interfaces, one or more input/output interfaces, or one or more operating systems, such as Windows Server, Mac OS X, Unix, Linux, FreeBSD, or the like.

For the purposes of this disclosure a “network” may be understood to refer to a network that may couple devices so that communications may be exchanged, such as between a server and a client device or other types of devices, including between wireless devices coupled via a wireless network, for example. A network may also include mass storage, such as network attached storage (NAS), a storage area network (SAN), or other forms of computer or machine-readable media, for example. A network may include the Internet, one or more local area networks (LANs), one or more wide area networks (WANs), wire-line type connections, wireless type connections, cellular or any combination thereof. Likewise, sub-networks, which may employ differing architectures or may be compliant or compatible with differing protocols, may interoperate within a larger network. Various types of devices may, for example, be made available to provide an interoperable capability for differing architectures or protocols. As one illustrative example, a router may provide a link between otherwise separate and independent LANs.

A communication link or channel may include, for example, analog telephone lines, such as a twisted wire pair, a coaxial cable, full or fractional digital lines including T1, T2, T3, or T4 type lines, Integrated Services Digital Networks (ISDNs), Digital Subscriber Lines (DSLs), wireless links including satellite links, or other communication links or channels, such as may be known to those skilled in the art. Furthermore, a computing device or other related electronic devices may be remotely coupled to a network, such as via a wired or wireless line or link, for example.

For purposes of this disclosure, a “wireless network” or communication link may be understood to couple client devices with a network. A wireless network may employ stand-alone ad-hoc networks, mesh networks, Wireless LAN (WLAN) networks, cellular networks, or the like. A wireless network may further include a system of terminals, gateways, routers, or the like coupled by wireless radio links, or the like, which may move freely, randomly or organize themselves arbitrarily, such that network topology may change.

A wireless network may further employ a plurality of network access technologies, including Wi-Fi, Long Term Evolution (LTE), WLAN, Wireless Router (WR) mesh, or 2nd, 3rd, or 4th generation (2G, 3G, or 4G) cellular technology, or the like. Network access technologies may enable wide area coverage for devices, such as client devices with varying degrees of mobility, for example.

For example, a network may enable RF or wireless type communication via one or more network access technologies, such as Global System for Mobile communication (GSM), Universal Mobile Telecommunications System (UMTS), General Packet Radio Services (GPRS), Enhanced Data GSM Environment (EDGE), 3GPP Long Term Evolution (LTE), LTE Advanced, Wideband Code Division Multiple Access (WCDMA), Bluetooth, 802.11b/g/n, or the like. A wireless network may include virtually any type of wireless communication mechanism by which signals may be communicated between devices, such as a client device or a computing device, between or within a network, or the like.

A computing device may be capable of sending or receiving signals, such as via a wired or wireless network, or may be capable of processing or storing signals, such as in memory as physical memory states, and may, therefore, operate as a server. Thus, devices capable of operating as a server may include, as examples, dedicated rack-mounted servers, desktop computers, laptop computers, set top boxes, integrated devices combining various features, such as two or more features of the foregoing devices, or the like. Servers may vary widely in configuration or capabilities, but generally a server may include one or more central processing units and memory. A server may also include one or more mass storage devices, one or more power supplies, one or more wired or wireless network interfaces, one or more input/output interfaces, or one or more operating systems, such as Windows Server, Mac OS X, Unix, Linux, FreeBSD, or the like.

For purposes of this disclosure, a client (or user) device may include a computing device capable of sending or receiving signals, such as via a wired or a wireless network. A client device may, for example, include a desktop computer or a portable device, such as a cellular telephone, a smart phone (iPhone or Android or something else), a display pager, a radio frequency (RF) device, an infrared (IR) device an Near Field Communication (NFC) device, a Personal Digital Assistant (PDA), a handheld computer, a tablet computer, a phablet, a laptop computer, a set top box, a wearable computer, smart watch, an integrated or distributed device combining various features, such as features of the forgoing devices, or the like.

A client device or mobile device may vary in terms of capabilities or features. Claimed subject matter is intended to cover a wide range of potential variations. For example, a simple smart phone, phablet or tablet may include a numeric keypad or a display of limited functionality, such as a monochrome liquid crystal display (LCD) for displaying text. In contrast, however, as another example, a web-enabled client device may include a high-resolution screen, one or more physical or virtual keyboards, mass storage, one or more accelerometers, one or more gyroscopes, global positioning system (GPS) or other location-identifying type capability, or a display with a high degree of functionality, such as a touch-sensitive color 2D or 3D display, for example.

A client device may include or may execute a variety of operating systems, including a personal computer operating system, such as a Windows, iOS or Linux, or a mobile operating system, such as iOS, Android, or Windows Mobile, or the like.

A client device may include or may execute a variety of possible applications, such as a client software application enabling communication with other devices, such as communicating one or more messages, such as via email, for example Google® Gmail, Yahoo!® Mail, short message service (SMS), or multimedia message service (MMS), for example Yahoo! Messenger®, including via a network, such as a social network, including, for example, Tumblr®, Facebook®, LinkedIn®, Twitter®, Flickr®, or Google+®, Instagram®, to provide only a few possible examples. A client device may also include or execute an application to communicate content, such as, for example, textual content, multimedia content, or the like. A client device may also include or execute an application to perform a variety of possible tasks, such as browsing, searching, playing or displaying various forms of content, including locally stored or streamed video, or games (such as fantasy sports leagues). The foregoing is provided to illustrate that claimed subject matter is intended to include a wide range of possible features or capabilities.

While numerous examples are given above, some additional examples follow.

Example 1. A network-based manufacturing system for electronic circuits including:
a plurality of work cells;
a warehouse having a plurality of storage bins;
a shuttle for moving items from the plurality of storage bins to the plurality of work cells;
a control unit communicatively coupled to the shuttle and the plurality of work cells;
a user interface for receiving an electronic circuit design;
wherein the control unit has a processor and non-transitory memory operable to have the shuttle pick up necessary components for the circuit design from the warehouse, deliver the components to an assigned work cell, assemble the components onto a scaffold, and couple pre-bent wires onto the components; and
wherein the components are coupled to the scaffold using machine pins positioned by one or more pincers in the assigned work cell.

Example 2. A network-based manufacturing system for electronic circuits including:
a plurality of work cells, wherein each work cell of the plurality of work cells includes:
a plurality of work cell pincers for holding, releasing and moving items, and
a work cell drawer moveable between a build position and a load position;
a plurality of storage bins for holding electronic components or pre-built circuits, each storage bin of the plurality of storage bins including a storage drawer that is moveable between a storage position and a loading position;
a shuttle for moving items from the plurality of storage bins to the plurality of work cells, wherein the shuttle includes:
one or more elevated rails suspended above the plurality of work cells and above the plurality of storage bins,
a transport cradle for releasably coupling to an item to be transported,
a plurality of adjustable legs coupled to the transport cradle,
a kinetic member associated with the one or more elevated rails for moving the kinetic member along the one or more elevated rails, and
a plurality of adjustable legs coupled to the transport cradle and to the kinetic member for holding and positioning the transport cradle at a desired height; and
a control unit having at least one processor and one non-transitory memory and communicatively coupled at least to the plurality of work cells and the shuttle and programmed to deliver components to the work cell and to assemble components on to a scaffold.

Example 3. The network-based manufacturing system of Example 2, wherein each work cell of the plurality of work cells further includes a test panel.

Example 4. The network-based manufacturing system of Examples 2 or 3, further including a plurality of camera systems with one camera system associated with each of the plurality of work cells, and wherein each camera system is operable to move within its associated work cell to view assembly of a circuit therein.

Example 5. A method of manufacturing a circuit or assembly by a user at a remote location over a network, the method including the steps of:
preparing a circuit or assembly design and uploading into a circuit build system;
determining the necessary components for the circuit or assembly design;
using a shuttle to retrieve the necessary components from a plurality of storage bins;
delivering with the necessary components to a work cell using the shuttle;
providing a scaffold having a grid of pinholes for receiving machine pins;
using one or more pincers to place the necessary components at designated locations on the scaffold for the circuit or assembly design;
coupling the necessary components to the scaffold using machine pinholes inserted into the pinholes on the scaffold; and
coupling pre-bent wires prepared with respect to length and bends to electrically couple the necessary components on the scaffold to complete a build of the circuit or assembly design.

Example 6. The method of Example 5, wherein the scaffold includes a base scaffold and a sub-scaffold.

Unless otherwise indicated, as used throughout this document, “or” does not require mutual exclusivity. The term “circuit” is used broadly and includes circuit assemblies, e.g., the circuit and attached components including motors, fans, solenoids, air compressors, electromagnets, lights, sensors, displays, etc. Circuit assembly further includes all of the test equipment for a circuit like oscilloscopes, hot ovens to heat the components and test that they continue to work, cold ovens, humidity ovens, drop tests, UV exposure, etc. Assemblies can also have the plastic or metal structure of a robot; one could have a 3d print of that in the factory and have it brought to one's work cell and one's circuit could be attached to it.

Although the present disclosure and its advantages have been disclosed in the context of certain illustrative, non-limiting embodiments, it should be understood that various changes, substitutions, permutations, and alterations can be made without departing from the scope of the disclosure as defined by the claims. It will be appreciated that any feature that is described in a connection to any one embodiment may also be applicable to any other embodiment.

What is claimed:

1. A work cell, comprising,
at least one scaffold base for supporting the assembly of an electronic device or an electronic circuit, wherein the at least one scaffold base comprises a flat rigid material having a plurality of apertures arranged in a repeating geometric pattern, wherein at least some of the apertures of the plurality of apertures are sized and configured to receive machine pins;
a rigid framework, for supporting the at least one scaffold base and coupled to the at least one scaffold base;
at least one pincer support slidably coupled to the rigid framework;
at least one pincer, slidably coupled to the at least one pincer support, for manipulating components of the electronic device or of the electronic circuit;
a first drive unit, comprising a first electric motor, coupled to the at least one pincer support, wherein the first drive unit is capable of moving the at least one pincer support in a first direction along a length of a first member of the rigid framework;
a second drive unit, comprising a second electric motor, coupled to the at least one pincer, for moving the at least one pincer in a second direction along a length of the at least one pincer support; and
wherein the at least one pincer comprises:
a pincer bar slidably coupled to the at least one pincer support,
a third drive unit, comprising a third electric motor, coupled to the pincer bar, wherein the third drive unit is capable of moving the pincer bar in a third direction, and
a pincer subassembly coupled proximate to a first end of the pincer bar, wherein movement of the pincer bar in the third direction results in movement of the pincer subassembly in the third direction,
wherein the pincer subassembly comprises,
a plurality of pincer arms coupled to a pincer arm support, wherein at least one of the pincer arms is slidably coupled to the pincer arm support, and
a fourth drive unit, comprising a fourth electric motor, for moving the least one pincer arm that is slidably coupled to the pincer arm support along a length of the pincer arm support.

2. The work cell of claim 1,
wherein the plurality of pincer arms comprises a first and second pincer arm;
wherein the first pincer arm is fixed in place on the pincer arm support and the second pincer arm is slidably coupled to the pincer arm support; and
wherein movement of the second pincer arm along the length of the pincer arm support results in increasing or decreasing a distance between pincer tips of the first pincer arm and the second pincer arm.

3. The work cell of claim 2, wherein the pincer arm subassembly is capable of clamping, manipulating, and releasing the components of the electronic device or of the electronic circuit.

4. The work cell of claim 3, wherein the pincer arm subassembly is capable of mounting the components of the electronic device or of the electronic circuit onto the at least one scaffold base by aligning at least one of the plurality of apertures sized and configured to receive machine pins with a machine pin of at least one of the components of the electronic device or of the electronic circuit.

5. The work cell of claim 1,
wherein the at least one scaffold base is slidably coupled to the rigid framework so the at least one scaffold base may be moved between an extended position and a not extend position; and
wherein when the at least one scaffold base is in the not extended position the at least one scaffold base is located within a space defined by the framework and when the at least one scaffold base is in the extended position at least a portion of the at least one scaffold base extends beyond the space defined by the framework.

6. The work cell of claim 1, further comprising a control board coupled to the rigid framework.

7. The work cell of claim 6, wherein the control board comprises a plurality of electrical connections which may be electrically coupled to the electronic device or electronic circuit.

8. The work cell of claim 7, wherein the plurality of electrical connections includes at least one of a power connection, an ethernet connection, a USB connection, or an oscilloscope connection.

9. The work cell of claim 1,
wherein the at least one pincer support comprises a first pincer support and a second pincer support;
wherein the at least one pincer comprises four pincers; and
wherein two pincers are coupled to the first pincer support and two pincers are coupled to the second pincer support.

10. The work cell of claim 1,
further comprising a drive belt coupled to the third electric motor and coupled to the pincer subassembly.

11. A work cell for assembling and prototyping an electronic device, comprising:
a framework comprised of a plurality of support beams;
a plurality of pincers moveably coupled to the framework;
a first scaffold base coupled to the framework comprising a flat surface for assembly of an electronic device, wherein a plurality of apertures are formed within the first scaffold base for retaining a plurality of electronic components of the electronic device;
a plurality of motors coupled to the framework or pincers for moving the pincers within the work cell;
wherein each of the plurality of pincers is capable of clamping onto, moving, and placing each of the electronic components within the work cell.

12. The work cell of claim 11,
wherein the plurality of apertures of the first scaffold base comprises a plurality of machine pin holes sized and configured to receive machine pins and a plurality of slots each sized and configured to receive a retaining clip.

13. The work cell of claim 12,
wherein at least one of the plurality of electronic components of the electronic device is mounted onto a second scaffold;
wherein the second scaffold comprises a plurality of slots each sized and configured to receive the retaining clip;
wherein the plurality of pincers is capable of mounting the second scaffold onto the first scaffold by aligning at least one of the slots of the plurality of slots of the first scaffold with at least one of the slots of the plurality of slots of the second scaffold and inserting the retaining clip into the aligned slots.

14. The work cell of claim 11,
wherein the plurality of support beams comprises at least one pincer support and at least one framework member;
wherein the at least one pincer support is slidably coupled to the at least one framework member; and
wherein the plurality of motors comprises an electric motor coupled to the at least one pincer support for moving the at least one pincer support along a length of the at least one framework member.

15. The work cell of claim 14,
wherein the at least one pincer support comprises a first pincer support and a second pincer support;
wherein the at least one framework member comprises a first framework member and a second framework member;
wherein the first pincer support is coupled to the first framework member;
wherein the second pincer support is coupled to the second framework member
wherein the plurality of pincers comprises four pincers; and
wherein two pincers are coupled to the first pincer support and two pincers are coupled to the second pincer support.

16. A work cell for assembling and prototyping an electronic device, comprising:
a framework comprised of a plurality of support beams;
a plurality of pincers moveably coupled to the framework;
a first scaffold base coupled to the framework comprising a flat surface for assembly of an electronic device, wherein a plurality of apertures are formed within the first scaffold base for retaining a plurality of electronic components of the electronic device;
a plurality of motors coupled to the framework or pincers for moving the pincers within the work cell;
wherein each of the plurality of pincers is capable of clamping onto, moving, and placing each of the electronic components within the work cell;
wherein the work cell is communicatively coupled to a control unit for transmitting commands from the control unit to the work cell;
wherein the commands comprise instructions for the work cell to assemble the electronic device.

17. The work cell of claim 16,
wherein the plurality of apertures of the first scaffold base comprises a plurality of machine pin holes sized and configured to receive machine pins and a plurality of slots each sized and configured to receive a retaining clip.

18. The work cell of claim 17,
wherein at least one of the plurality of electronic components of the electronic device is mounted onto a second scaffold;
wherein the second scaffold comprises a plurality of slots each sized and configured to receive the retaining clip;
wherein the plurality of pincers is capable of mounting the second scaffold onto the first scaffold by aligning at least one of the slots of the plurality of slots of the first scaffold with at least one of the slots of the plurality of slots of the second scaffold and inserting the retaining clip into the aligned slots.

19. The work cell of claim 16,
wherein the plurality of support beams comprises at least one pincer support and at least one framework member;
wherein the at least one pincer support is slidably coupled to at least one framework member; and
wherein the plurality of motors comprises an electric motor coupled to the at least one pincer support for moving the at least one pincer support along a length of the at least one framework member.

20. The work cell of claim 19,
wherein the at least one pincer support comprises a first pincer support and a second pincer support;
wherein the at least one framework member comprises a first framework member and a second framework member;
wherein the first pincer support is coupled to the first framework member;
wherein the second pincer support is coupled to the second framework member
wherein the plurality of pincers comprises four pincers; and
wherein two pincers are coupled to the first pincer support and two pincers are coupled to the second pincer support.
